(19) United States
(12) Patent Application Publication
(10) Pub. No.: US 2026/0090432 A1
(43) Pub. Date: Mar. 26, 2026

(54) METHODS AND SYSTEMS FOR FORMING INTEGRATED CIRCUIT PACKAGES COMPRISING GLASS LAYERS WITH THIN SINGULATED PORTIONS

(71) Applicant: Intel Corporation, Santa Clara, CA (US)

(72) Inventors: Jeremy D. Ecton, Gilbert, AZ (US); Brandon Christian Marin, Gilbert, AZ (US); Hanyu Song, Chandler, AZ (US); Hiroki Tanaka, Gilbert, AZ (US); Whitney M. Bryks, Tempe, AZ (US); Haobo Chen, Chandler, AZ (US); Gang Duan, Chandler, AZ (US); Benjamin T. Duong, Phoenix, AZ (US); Yonggang Li, Chandler, AZ (US); Robert A. May, Chandler, AZ (US); Bai Nie, Chandler, AZ (US); Srinivas Venkata Ramanuja Pietambaram, Chandler, AZ (US); Bohan Shan, Chandler, AZ (US); Jacob Vehonsky, Chandler, AZ (US); Fanyi Zhu, Gilbert, AZ (US)

(21) Appl. No.: 18/898,372

(22) Filed: Sep. 26, 2024

(51) Int. Cl. H01L 23/498; H01L 23/13; H01L 23/14; H01L 25/065

(52) U.S. Cl. CPC H10W 70/685; H10W 70/68; H10W 70/695; H10W 90/00

(57) ABSTRACT

An apparatus comprising a package substrate, the package substrate comprising a glass structure; at least one buildup layer above the glass structure; and at least one buildup layer below the glass structure; wherein the glass structure comprises a first portion having a first thickness and a second portion that extends outward from the first portion, wherein the second portion has a second thickness that is smaller than the first thickness.

### BACKGROUND

A package substrate may be used in an electronic device to provide electrical and mechanical support to integrated circuit components coupled thereto. A package substrate may host a network of conductive traces that connect various components on the surface of the package substrate. The package substrate may also feature conductive pathways (e.g., vias) that traverse the layers of the substrate, enabling connections between different layers of the package substrate. In some instances, a package substrate may provide electrical connection between one or more integrated circuit components and various circuits of a printed circuit board upon which the package substrate is mounted.

### BRIEF DESCRIPTION OF THE DRAWINGS

FIGS. 1 and 2 illustrate cross sections of various phases of manufacture of a package substrate with a glass core and thin glass protrusions, in accordance with any of the embodiments disclosed herein.

FIG. 3 illustrates top down views of a phase of manufacture of a glass structure comprising thin glass protrusions in accordance with any of the embodiments disclosed herein.

FIGS. 4 and 5 illustrate cross sections of various phases of manufacture of a portion of a package substrate comprising a glass structure with at least one glass protrusion, in accordance with any of the embodiments disclosed herein.

FIG. 6 illustrates a top down view of a glass panel with glass bridges between glass unit panels formed from a glass panel in accordance with any of the embodiments disclosed herein.

FIG. 7 illustrates cross sections of various phases of manufacture of package substrates comprising glass structures and glass protrusions, in accordance with any of the embodiments disclosed herein.

FIG. 8 illustrates a package substrate comprising a glass core with at least one glass protrusion, in accordance with any of the embodiments disclosed herein.

FIG. 9 illustrates cross sections of various phases of manufacture of package substrates comprising glass cores and protrusions at varying heights, in accordance with any of the embodiments disclosed herein.

FIG. 10 illustrates cross sections of various phases of manufacture of package substrates comprising glass cores and protrusions at varying heights, in accordance with any of the embodiments disclosed herein.

FIG. 11 illustrates cross sections of various phases of manufacture of a package substrate comprising a glass core and at least one glass protrusion, in accordance with any of the embodiments disclosed herein.

FIG. 12 illustrates a package substrate comprising a glass core and at least one glass protrusion, in accordance with any of the embodiments disclosed herein.

FIG. 13 illustrates a perspective view of a phase of manufacture of a package substrate comprising a glass core and at least one glass protrusion, in accordance with any of the embodiments disclosed herein.

FIG. 14 illustrates an integrated circuit package comprising a glass core and a glass protrusion, in accordance with any of the embodiments disclosed herein.

FIG. 15 provides a schematic illustration of a cross-sectional view of an example integrated circuit device, in accordance with any of the embodiments disclosed herein.

FIG. 16 is a top view of a wafer and dies that may be included in a microelectronic assembly, in accordance with any of the embodiments disclosed herein.

FIG. 17 is a cross-sectional side view of an integrated circuit device that may be included in a microelectronic assembly, in accordance with any of the embodiments disclosed herein.

FIGS. 18A-18D are perspective views of example planar, FinFET, gate-all-around, and stacked gate-all-around transistors.

FIG. 19 is a cross-sectional side view of an integrated circuit device assembly that may include a microelectronic assembly, in accordance with any of the embodiments disclosed herein.

FIG. 20 is a block diagram of an example electrical device that may include a microelectronic assembly, in accordance with any of the embodiments disclosed herein.

### DETAILED DESCRIPTION

In some implementations, a package substrate may comprise a glass core sandwiched between buildup layers. Recently, glass cores have been explored as alternatives to organic resin-based cores (e.g., cores based on Ajinomoto Buildup Film (ABF)). For a variety of reasons, glass is expected to improve the mechanical and electrical performance of semiconductor substrate packages over other core materials. For example, glass is considered more rigid than organic resin-based materials and may have several advantages such as excellent thermal properties, a low coefficient of thermal expansion (CTE), high thru-hole density, improved dimensional stability, high electrical insulation, chemical resistance, optical transparency, and compatibility with advanced semiconductor properties. In some instances, glass cores may facilitate transmission of high frequency signals within the package. As another example, glass cores also allow improved coplanarity over cores made from organic materials.

Implementing a glass core can introduce a variety of technical challenges and reliability issues. A major challenge for widespread adoption of glass cores is the susceptibility of the glass to damage due to mechanical and/or thermal stresses. For example, glass core substrates with a high number of buildup layers have a high risk of glass splitting in the core due to internal residual buildup stress as well as CTE mismatch between the core and buildup layers. During a depaneling or singulation step, any defects introduced during any of the upstream process steps in the glass core material coupled / high CTE mismatch between the glass core and buildup material can easily lead to glass separation. The risk of glass splitting is especially high for thicker core substrates.

Crack formation and propagation in glass compromises the structural integrity of glass, making microelectronic assemblies with glass cores particularly prone to failure over time. Embodiments of the present disclosure relate to various techniques, as well as to related devices and methods, for alleviating (e.g., mitigating or reducing) crack formation and propagation in glass structures used to form glass cores used in integrated circuit packages.

Various embodiments of the present disclosure provide package substrates which include glass protrusions which extend from a glass core, wherein the glass protrusions are thinner than the glass core. The glass protrusions are formed by singulation of relatively thin glass regions extending from the glass core.

Various embodiments may provide one or more advantages, such as increased protection against glass cracking during the manufacturing process, reduced manufacturing cost, improved yield, or reduced complexity in manufacturing processes.

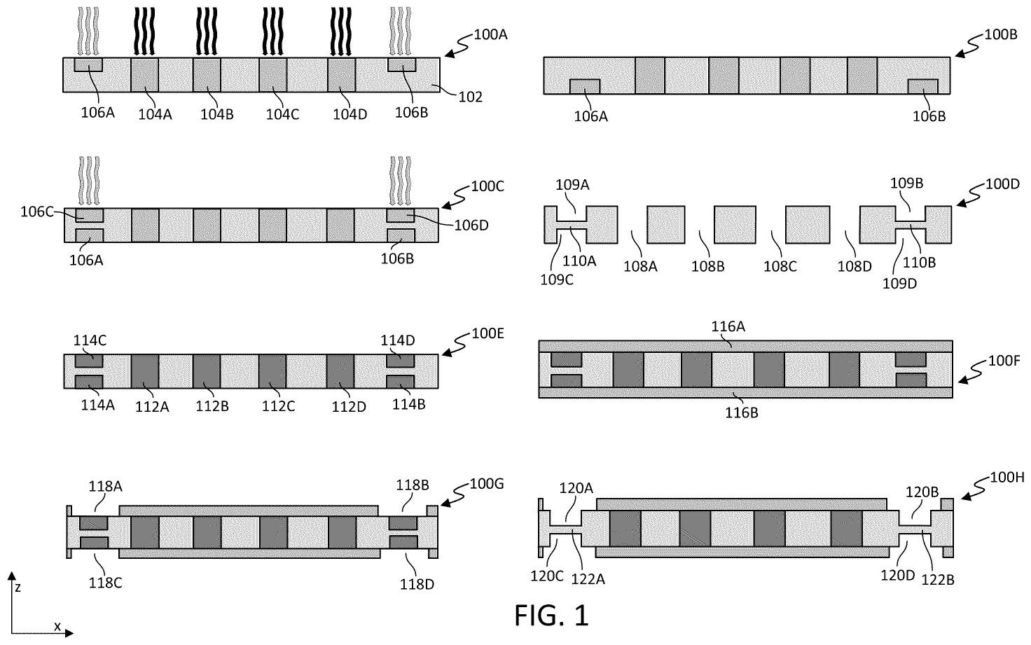

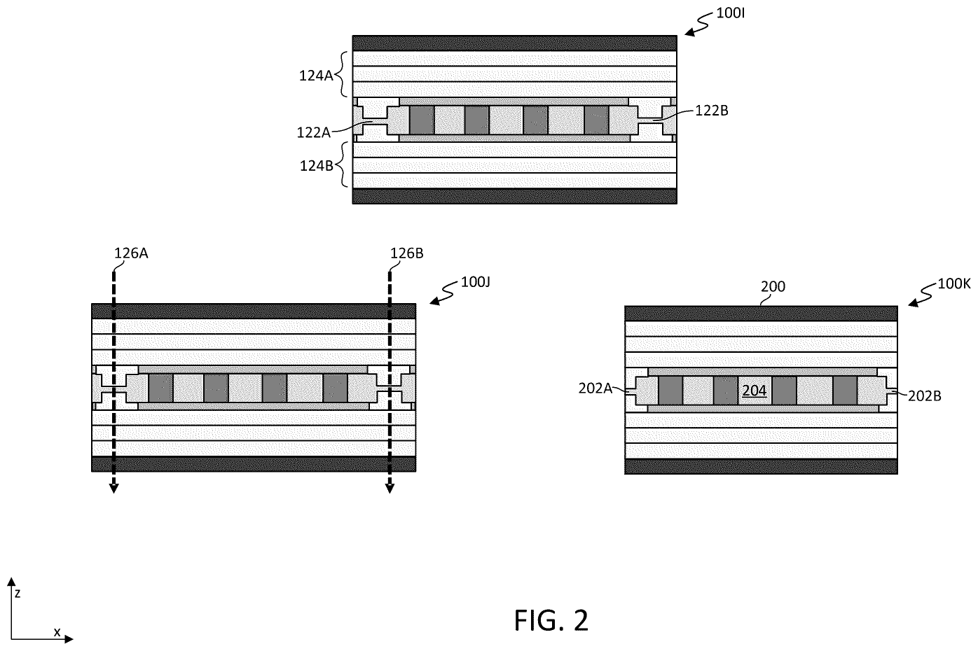

FIGS. 1 and 2 illustrate cross sections of various phases of manufacture of a package substrate with a glass core and thin glass protrusions, in accordance with any of the embodiments disclosed herein.

At phase 100A a glass structure 102 is positioned. The glass structure 102 shown may be at least a portion of a glass panel, glass subpanel, or glass unit, for example. At least one laser may then be applied to the glass structure 102 (e.g., as part of a laser assisted etching process). For example, a first laser is applied to various portions (e.g., portions 104A-D) and a second laser is applied to other portions (e.g., portions 106A-B). In another example, the same laser may be applied to the portions 104 and 106, but with different characteristics (e.g., with different powers, with different beam shapes, with different exposure times, etc.) for each group of portions. In operation, the application of the laser(s) to portions of the glass structure 102 causes a change in the properties (e.g., alters the chemistry) of the portions (e.g., to make these portions more sensitive to an etch to be applied later such that the etching is much faster in the regions activated by the laser). In one embodiment, a laser is applied to the portions 104A-D using a first power and the laser is applied to the portions 106A-B using a second power that is less than the first power. The laser activates portions 104A-D across the entire thickness (in the z-direction) of the glass structure 102, while the laser activates portions 106A-B only across a portion of the thickness of the glass structure 102. The portions 104A-D may represent areas in which TGVs are to be formed in the glass structure 102, while the portions 106A and B are at the perimeter of a glass core for a package substrate to be formed from the glass structure 102.

At phase 100B, the structure is flipped over so that the portions 106A and 106B are now on the bottom of the glass structure 102. At phase 100C, a laser is applied to portions 106C and 106D. Portions 106C and 106D may be on an opposite side of the glass structure 102 from portions 106A and 106B and may at least partly overlap in the x-direction and y-direction with portions 106A and 106B. In some embodiments, one or more settings of a laser that is applied to portions 106A and 106B may be the same as the laser applied to portions 106C and 106D (e.g., this laser may use less power than the laser used for portions 104A-D). In various embodiments, portions 106A and 106C do not overlap in the z-direction and portions 106B and 106D also do not overlap in the z-direction (such that a portion of the glass structure 102 in between the respective portions is not materially affected by the laser).

Any suitable laser may be used in phases 100A and 100C, such as a picosecond laser (e.g., a green laser or an infrared laser). In some embodiments, flipping of the glass structure in phase 100B may be omitted by changing the light focus.

At phase 100D, an etch is performed. The portions of the glass that were modified by the laser(s) are sensitive to the etch and are readily removed by the etch to create voids in the glass structure 102. After portions 106A-D are removed, glass bridges 110A and 110B of the glass structure 102 are still present (e.g., as they were not materially affected by the laser and were not removed by the etch). These glass bridges 110A and 110B connect thicker portions of glass together. Shallow trenches 109A-D are formed on either side of the glass bridges 110A and 110B. Through-holes 108A, 108B, and 108C, 108D are also formed (e.g., in preparation for forming TGVs).

In various embodiments (including any of those described herein), portions of glass structures may be removed by laser assisted etching as described above or by any other suitable means, such as through mechanical drilling (using drill bits, blasts, or other methods), laser ablation, chemical methods (e.g., etching), or other suitable methods.

At phase 100E, the voids formed in phase 100D are filled with a conductive material (e.g., comprising a metal such as copper) to form TGVs 112A, 112B, 112C, and 112D and conductive portions 114A, 114B, 114C, and 114D. While in this embodiment, the voids are filled with the same conductive material, in other embodiments, the thru-holes 108 and the trenches 109 could be filled with different materials (e.g., the trenches 109 could be filled with a dielectric material or other material that is different from the material used to form the TGVs 112A-112D).

At phase 100F, a first buffer layer 116A is formed over one side of the glass structure 102, the TGVs 112A-D, and the conductive portions 114C and 114D. The glass structure 102 may be turned over and a second buffer layer 116B formed over the other side of the glass structure 102, the TGVs 112A-D, and the conductive portions 114A and 114B. The buffer layers 116A and 116B may include the same material or may be different materials. In various embodiments, one or both of the buffer layers comprise a dielectric material, such as a polymer material. For example, a buffer layer may comprise an ABF or a photo imageable dielectric (PID). In some embodiments, one or both of the buffer layers may comprise any suitable buildup material, such as one of the buildup materials described herein. The buffer layers may be formed in any suitable manner, such as through coating or laminating.

At phase 100G, portions of the buffer layer are removed to form trenches 118A-118D. The trenches may be formed over at least a portion of the surfaces of the conductive portions 114A-114D. Any suitable method may be used to remove portions of the buffer layer. For example, a lithography patterning process (e.g., including dry etching) may be used (e.g., if the buffer layer includes PID) or a laser skiving process may be used (e.g., if the buffer layer includes ABF).

At phase 100H, the material within conductive portions 114A-D is removed to form trenches 120A-120D and glass bridges 122A and 122B. For example, the material may be etched.

At phase 100I, various first buildup layers 124A are formed over one side of the glass structure 102 and the structure may be flipped over and various second buildup layers 124B may be formed over the other side of the glass structure 102. One or more of these layers may also be formed within the trenches 118A-118D and 120A-120D. For example, in some embodiments, a lamination process may cause material of a buildup layer to become molten and to flow into the trenches. Interconnect material may also be formed within the buildup layers 124A and/or 124B as described elsewhere herein (some of which may connect to one or more of the TGVs 112A-112D).

At phase 100J, the structure is singulated in any suitable manner along singulation paths 126A and 126B. For example, the singulation process may include one or more of laser ablation, mechanical sawing (e.g., using a metal blade), or breakage using mechanical force. The singulation paths cross through the glass bridges 122A and 122B. Accordingly, the thickness of the glass that is singulated is much smaller than if the singulation paths were to cross through the entire thickness of the glass structure 102. This may reduce the likelihood that the glass structure 102 cracks during singulation (or during subsequent processing based on a defect introduced through the singulation).

Phase 100K illustrates the resulting package substrate 200. As illustrated, the glass structure 102 may have a generally uniform thickness over a majority of its width (e.g., in the x-direction) and length (e.g., in the y-direction) (where this portion with generally uniform thickness may be referred to as glass core 204), but may have a significantly reduced thickness at its edges. For example, protrusions 202A and 202B (which extend outward from the glass core 204) have a much smaller thickness than the glass core 204. In some embodiments, the glass core 204 has a thickness in the range of 100 to 3000 microns, while the protrusions 202 have a thickness of between 25 and 200 microns. Other embodiments may include any other suitable dimensions for either the core or the protrusions.

In addition to a reduction in the chance of the glass breaking during singulation, the architecture may provide additional protection to the glass structure 102 through the dielectric material placed above and below the protrusions 202 (as the outer sides of the core 204 are now protected from exposure by the dielectric material).

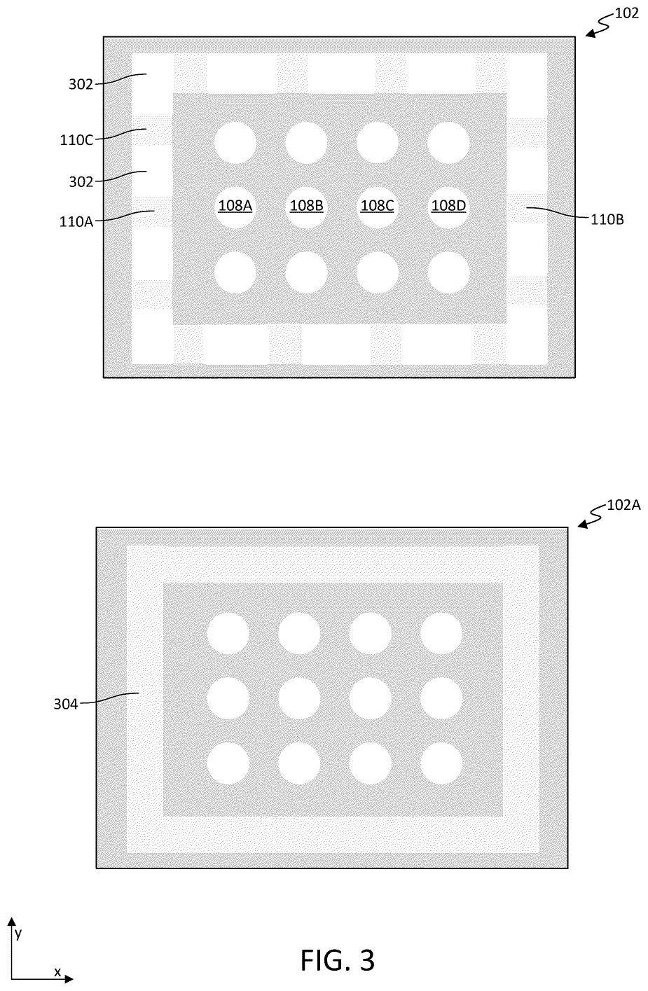

FIG. 3 illustrates top down views of a phase of manufacture of a glass structure comprising thin glass protrusions in accordance with any of the embodiments disclosed herein. The views may correspond to phase 100D of FIG. 1 (e.g., after the laser(s) have been applied and the etch has been performed to remove portions targeted by the laser(s)).

In glass structure 102, the glass bridges 110A and 110B are visible. As illustrated in FIG. 1, the glass above and beneath these bridges has been removed. The through-holes 108A-108D are also shown, along with other through-holes 302 formed around the perimeter of the portion of the glass structure 102 that is to be included in a package substrate. The perimeter includes alternating through-holes 302 (from which all of the glass has been removed by the etch) and glass bridges 110 (e.g., 110A-C). Although these through-holes and bridges are shown as having rectangular shapes through a cross section (e.g., in the x-y plane), any of these may have different shapes, such as circular, square, or other suitable shapes. In this embodiment, the alternating through-holes and bridges significantly reduces the volume of glass around the perimeter that is to be singulated to form the package substrates while still maintaining enough material between glass units (e.g., of a glass panel or glass quarter-panel) to provide sufficient structural support during processing prior to singulation. The through-holes 302 and the additional bridges 110 may be formed in like manner as that described above with respect to through holes 108A-D and bridges 110A and 110B.

In glass structure 102A, the perimeter does not include discrete alternating glass bridges and through-holes, but rather includes a single glass bridge 304 around the entire perimeter of the portion of the glass structure 102A that is to be included in a package substrate. As with glass bridges 110, the glass bridge 304 may have glass removed from above and below it (e.g., through application of a laser and etching). Thus, when referring to FIG. 1, the glass bridges 110A and 110B may represent portions of the glass bridge 304 that are on opposite sides (in the x-direction). After subsequent processing the glass bridge 304 may result in a glass structure 102A with a core having a first thickness (e.g., a maximum thickness) and a single protrusion formed from the glass bridge 304 (e.g., by singulating through the glass bridge) that extends out (e.g., in the x and y directions) from the core and encompasses the entire core, wherein the protrusion has a second thickness that is much smaller than the first thickness (e.g., less than half of the thickness, less than one fourth of the thickness, less than one sixth of the thickness, less than one-tenth of the thickness, etc.).

Herein when referring to a thickness of a glass structure (e.g., a glass core, a glass bridge, a glass protrusion, etc.), the thickness may refer to a maximum thickness of the relative glass structure (as the thickness of a particular structure could vary along the length or width of the structure).

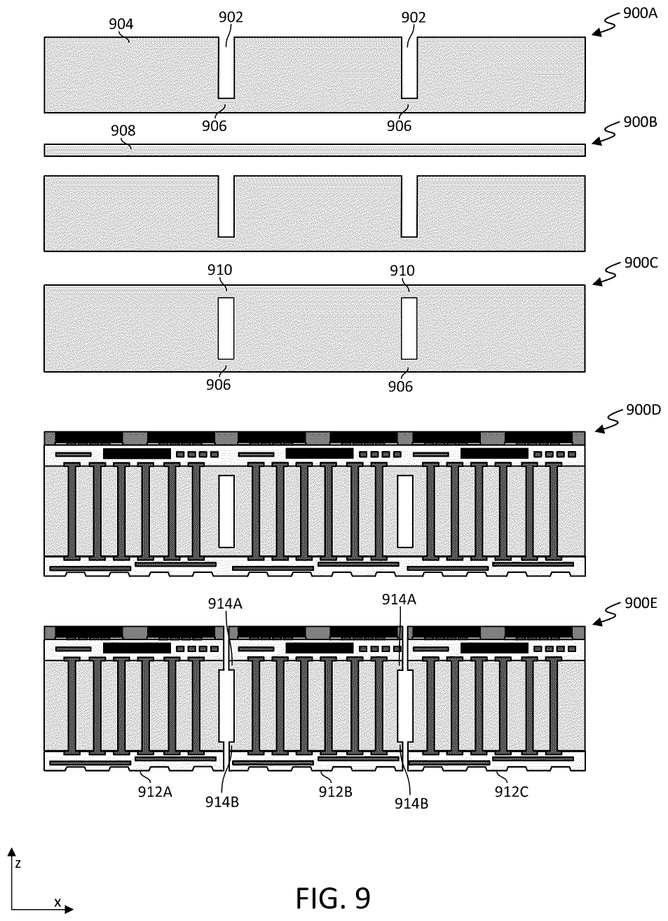

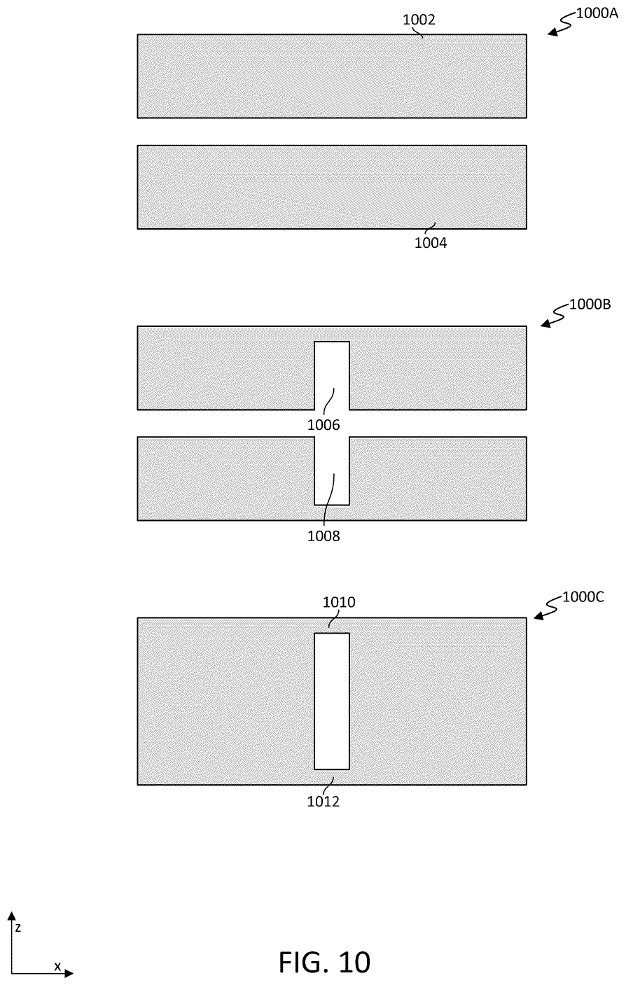

The embodiments depicted in FIG. 3 may be illustrative for other embodiments depicted herein (as many such embodiments only illustrate a cross section through the x-z plane). For example, any of the embodiments herein may include a single protrusion that extends from a glass core around an entire perimeter of the glass core (or multiple such protrusions at varying heights such as illustrated in FIGS. 9 and 10) or may include any number of discrete protrusions extending outward from various points on the perimeter of the glass core.

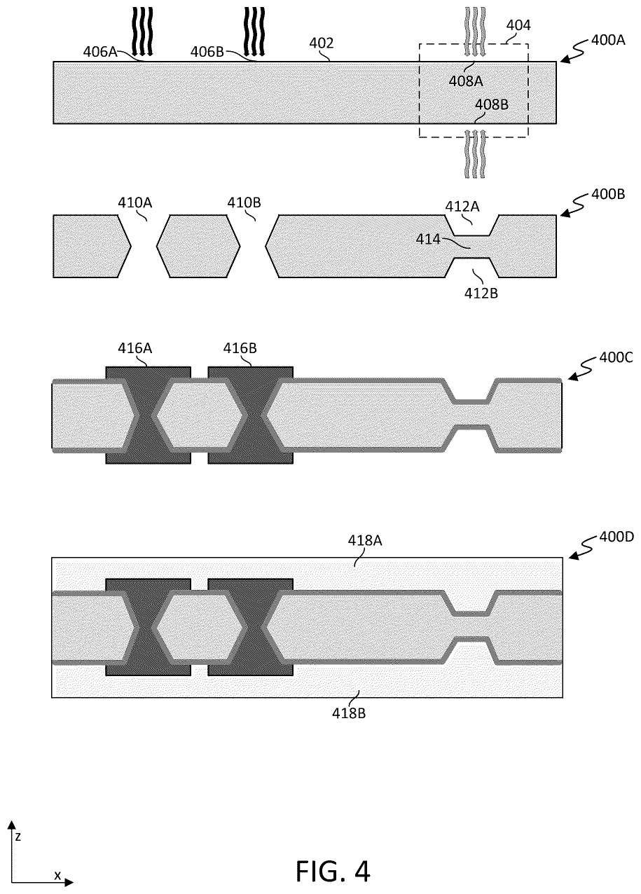

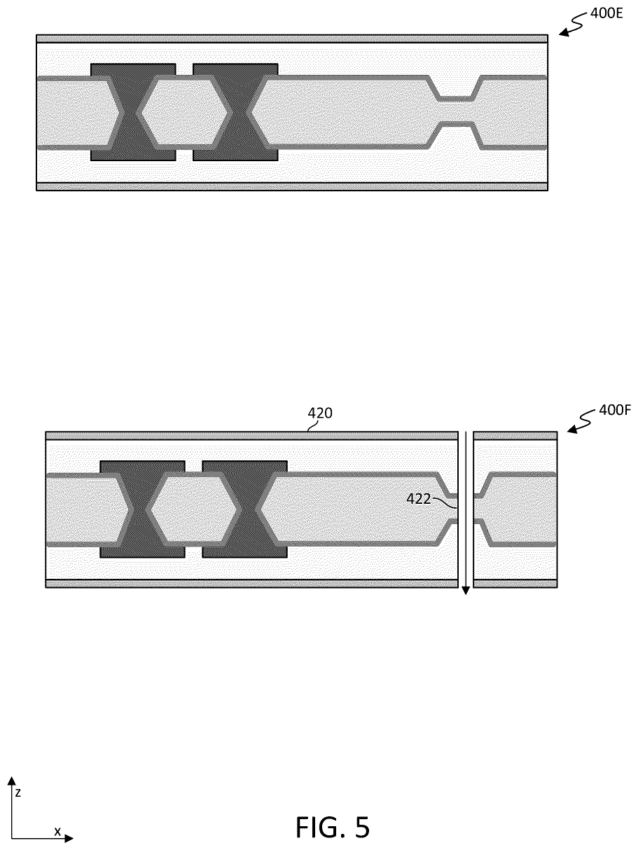

FIGS. 4 and 5 illustrate cross sections of various phases of manufacture of a portion of a package substrate comprising a glass structure with at least one glass protrusion, in accordance with any of the embodiments disclosed herein.

At phase 400A a glass structure 402 is positioned. The glass structure 402 shown may be at least a portion of a glass panel, glass subpanel, or glass unit, for example. The glass structure 402 may include an active area that may include interconnect (e.g., TGVs) or other circuitry and an inactive area 404 which will not include interconnect or other circuitry. The inactive area may include what may colloquially be referred to as a sawstreet area. The sawstreet area includes the area in which singulation will be performed. A glass core may include the active area (and optionally could include a portion of the inactive area).

In phase 400A a first laser is applied to the glass structure 402 at various locations 406A, 406B at which TGVs are to be formed in the active area. A second laser may also be applied to the top and bottom surfaces of the glass structure 402 in areas 408A, 408B within the inactive area 404. The laser that is applied within the inactive area may be different (e.g., in power, beam shape, exposure time, etc.) from the laser that is applied within the active area, such that it does not affect the entire thickness of the glass. As described above, the laser may change properties of the glass at these areas such that etching may be performed to remove the glass at these areas.

The laser applied within the inactive area may be applied across the entire outer perimeter of the glass structure (e.g., similar to the lower embodiment in FIG. 3) or at selected spots of that outer perimeter (e.g., similar to the upper embodiment in FIG. 3).

At phase 400B, an etching process is performed. The etch may remove the portions of glass that were modified by the laser in phase 400A. For example, the etch may create through-holes 410A and 410B as well as shallow trenches 412A and 412B (in some embodiments a single etching process may generate both types of voids). A glass bridge 414 may be formed between the main portion (e.g., core) of the glass structure 402 and glass that is substantially the same thickness as the main portion of the glass structure 402 (e.g., a core of an adjoining glass structure or an edge of glass that is not to be included in the singulated glass unit). In some embodiments, this etch may be an alkaline etch (e.g., NaOH or KOH).

At phase 400C, conductive material (e.g., copper) is placed within the through-holes 410A and 410B to form TGVs 416A and 416B.

At phase 400D, first buildup layers 418A are formed above (e.g., on) the TGVs 416A and 416B and the glass bridge 414. Second buildup layers 418B are formed below the TGVs 416A and 416B and below the glass bridge 414 (above these if the glass structure is flipped).

At phase 400E, a dielectric layer (e.g., a solder mask) and conductive contacts are formed on the first buildup layers 418A and a dielectric layer and conductive contacts are formed on the second buildup layers 418B.

At phase 400F, singulation is performed in the inactive area 404 through the dielectric layers, the buildup layers 418, and the glass bridge 414. In some embodiments, the singulation may include laser skiving to remove portions of the buildup layers (if these layers are too thick, mechanical singulation may be difficult) as well as cutting through (e.g., via laser or saw blade) or otherwise breaking the thin glass bridge 414.

This phase results in formation of a substrate package 420 with a glass protrusion 422 extending outwards from the thicker portion of the glass structure 402. In addition to providing a much thinner portion of glass to be singulated, the flow shown also presents an exposed glass sidewall (of the glass protrusion 422) that is relatively thin (and thus much less glass is exposed to potential damage during subsequent manufacturing operations than if the glass structure 402 had been singulated at a point having the same thickness as the active area).

After singulation (or before singulation), additional manufacturing operations may be performed, such as coupling of one or more semiconductor dies to the substrate package. In some instances, an edge coating may be applied to the sidewalls of the package substrate (and thus may be in contact with the sides of the glass protrusion(s).

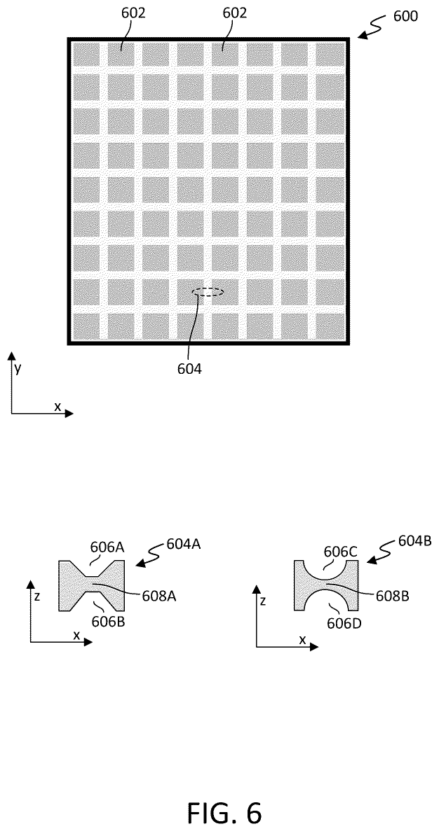

FIG. 6 illustrates a top down view of a glass panel with glass bridges between glass unit panels formed from a glass panel in accordance with any of the embodiments disclosed herein. The glass panel 600 is to be singulated into several unit panels 602 which will each form the core of a package substrate. FIG. 6 may correspond to phase 400B (after the laser selective etching has been performed), although the through-holes for the TGVs are not depicted.

FIG. 6 also depicts example interfaces 604 between two adjacent unit panels 602. Interface 604A has a first shape in which the shallow trenches 606A and 606B on either side of the glass bridge 608A (between the adjacent unit panels) have a generally trapezoidal shape. Interface 604B has a first shape in which the shallow trenches 606C and 606D on either side of the glass bridge 608B (between the adjacent unit panels) have a generally semicircular shape. In either embodiment, the center of the interface has a thin portion of glass (relative to the thickness of the other portions of the unit panels) that will be singulated when individual package substrates are formed from the glass panel 600.

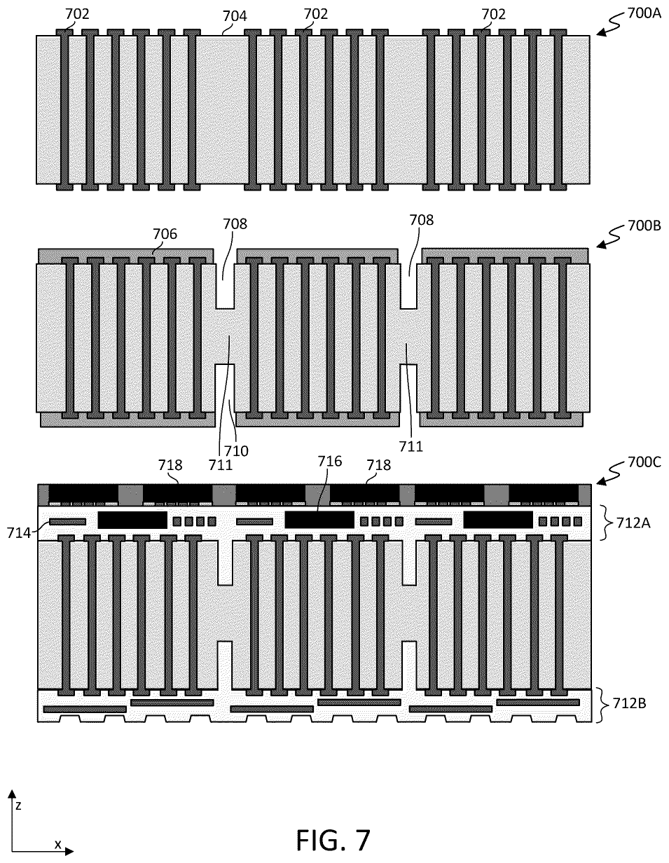

FIG. 7 illustrates cross sections of various phases of manufacture of package substrates comprising glass structures and glass protrusions, in accordance with any of the embodiments disclosed herein.

At phase 700A, TGVs 702 are formed at various locations in the glass structure 704 (e.g., glass panel, glass quarter panel, etc.) by removing portions of the glass and forming conductive material in the resulting through-holes.

At phase 700B, buffer layers 706A and 706B are formed over at least a portion of the active areas, such that the buffer layers 706A and 706B are formed over (e.g., on) the TGVs 702 and portions of the glass structure 704. A buffer layer 706A or 706B may include, e.g., a cover film (e.g., a polyethylene terephthalate (PET) film), a photoresist, or one of the materials described above for buffer layers 116A and 116B. The buffer layers 706A and 706B may be utilized during the formation of trenches 708 in inactive areas on one side of the glass structure 704 and trenches 710 on the other side of the glass structure 704, wherein the trenches 710 overlap at least partially with (in the x-y plane) corresponding trenches 708. The removal of glass to form trenches 708 and 708 results in formation of glass bridges 711 between thicker portions of glass. These glass bridges 711 will later be singulated to form individual package substrates.

At phase 700C, the buffer layers 706A and 706B are removed and additional processing is performed. For example, a plurality of buildup layers 712A and 712B are formed. In various embodiments, interconnects 714 and bridges 716 (e.g., that couple multiple integrated circuit dies 718 together) may be formed within the buildup layers 712A and/or 712B. Integrated circuit dies 718 may also be attached to the substrate packages. In other embodiments, any one or more of the additional processing steps (e.g., the assembly of the integrated circuit dies) may be performed after singulation of the individual package substrates.

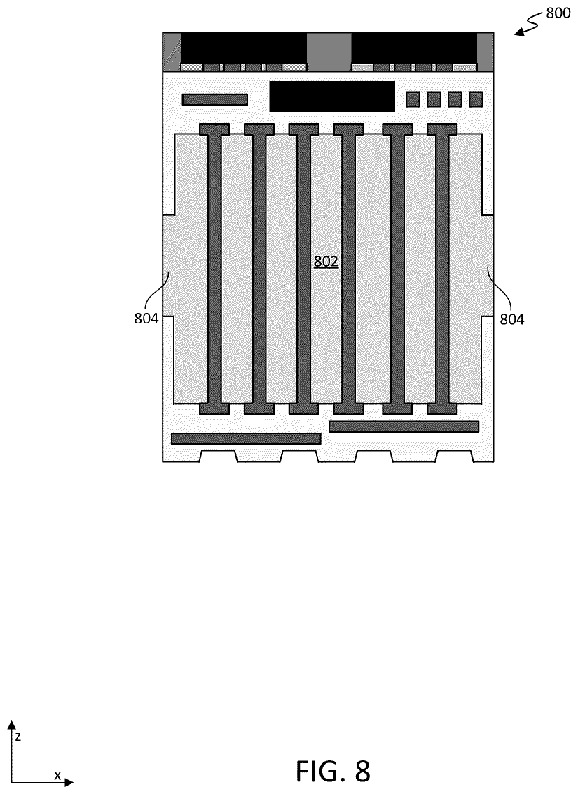

FIG. 8 illustrates a package substrate 800 comprising a glass core 802 with at least one glass protrusion 804, in accordance with any of the embodiments disclosed herein. The package substrate 800 is formed by singulating the glass bridges 711 (and any layers above and below the glass bridges 711). The package substrate 800 includes at least one protrusion 804 which includes portions of the glass bridges 711 that persist after singulation is performed.

FIG. 9 illustrates cross sections of various phases of manufacture of package substrates comprising glass cores and protrusions at varying heights, in accordance with any of the embodiments disclosed herein. For purposes of explanation, various elements (e.g., TGVs) may be omitted in the depiction of phases 900A-900C.

At phase 900A, trenches 902 are formed in a glass structure 904 (e.g., via application of a laser and etching or through other suitable means). In this embodiment, after removal of the glass to form the trenches 902, thin strips of glass (e.g., glass bridges 906) are present at the bottom of the glass structure 904 between thicker portions of the glass structure 904.

At phase 900B, a glass strip 908 is positioned with respect to the glass structure 904. In some embodiments, the glass strip 908 may have dimensions in the x-y plane that are equal to or substantially similar to the dimensions of the glass structure 904. In various embodiments, the glass strip 908 may have a thickness that is substantially equal to the thickness of the glass bridges 906 (in other embodiments the thickness may be different) and is much thinner than the glass structure 904.

At phase 900C, the glass strip 908 is coupled to the glass structure 904. This results in glass bridges 906 on the bottom of the combined glass structure and glass bridges 910 on the top of the combined glass structure.

Phase 900D shows the resulting structure after subsequent processing (e.g., formation of buildup layers, interconnect, bridges, coupling of dies, etc.). In phase 900E, singulation is performed to form individual package substrates 912A-C. The singulation may pass through glass bridges 906 and 910 and may result in formation of glass protrusions 914A at the top of the core of the glass structure and 914B at the bottom of the core of the glass structure.

FIG. 10 illustrates cross sections of various phases of manufacture of package substrates comprising glass cores and protrusions at varying heights, in accordance with any of the embodiments disclosed herein. For purposes of explanation, various elements (e.g., TGVs) may be omitted in the depiction of phases 1000A-1000C.

At phase 1000A, glass structure 1002 and glass structure 1004 are provided. In particular embodiments, the glass structure 1002 and glass structure 1004 have substantially equal dimensions. In other embodiments, the glass structures may have different dimensions (e.g., one of the glass structures may be thicker than the other).

At phase 1000B, trench 1006 is formed in glass structure 1002 and trench 1008 is formed in glass structure 1004. The trenches may be formed in any suitable manner, such as application of a laser and etching as described above or other suitable manner. In some embodiments, the voids have substantially the same dimensions (in other embodiments, one void may be taller, wider, etc.).

At phase 1000C, the glass structure 1002 is coupled to the glass structure 1004. This results in formation of glass bridge 1010 at the top of the combined glass structure and glass bridge 1012 at the bottom of the combined structure. Although not shown, subsequent processing may be performed (e.g., formation of buildup layers, interconnect, bridges, coupling of dies, etc.). Singulation may also be performed to form individual package substrates. The singulation may pass through glass bridges 1010 and 1012 and may result in formation of glass protrusions (from portions of the glass bridges 1010 and 1012, e.g., similar to the embodiment depicted in FIG. 9).

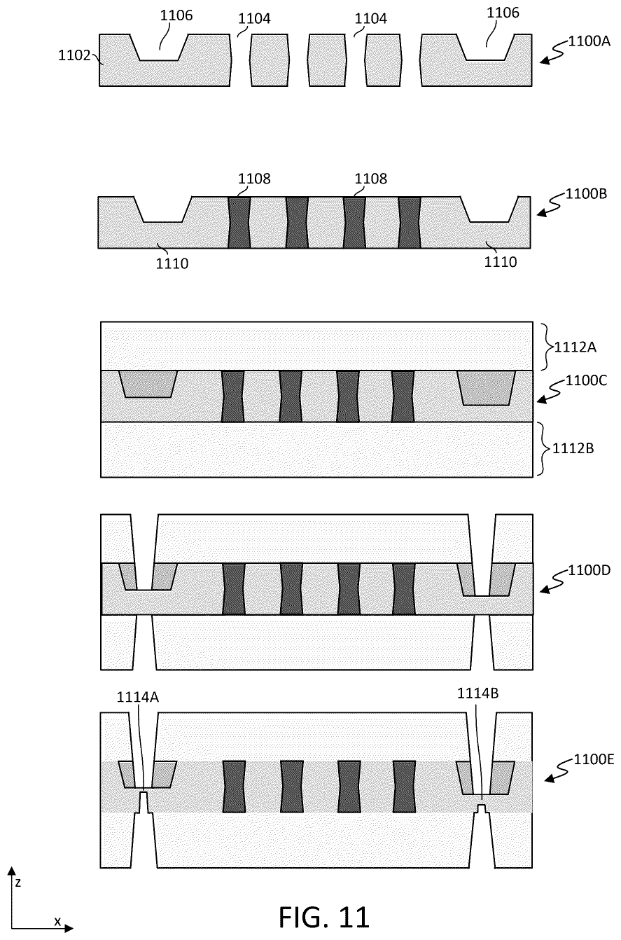

FIG. 11 illustrates cross sections of various phases of manufacture of a package substrate comprising a glass core and at least one glass protrusion, in accordance with any of the embodiments disclosed herein.

At phase 1100A, various voids are formed in a glass structure 1102. These voids may include through-holes 1104 for TGVs (that extend through the entire thickness of the glass structure 1102) as well as trenches 1106 around a perimeter of a portion of the glass structure 1102 (e.g., encompassing the area that includes the through-holes 1104). Trenches 1106 extend only through a portion of the thickness of the glass structure 1102. The voids may be formed in any suitable manner, such as through application of a laser and etching as described above or other suitable manner.

At phase 1100B, conductive material is placed within the through-holes 1104 to form TGVs 1108. For example, the conductive material may include copper formed using a plating process. During the formation of the conductive material, the trenches 1106 may be masked such that the conductive material is not placed in the trenches 1106.

At phase 1100C, various buildup layers 1112A and 1112B are formed on either side of the glass structure 1102. As depicted, the trenches 1106 may be filled with a dielectric material (e.g., the first buildup layer placed on the top of the glass structure 1102 or another dielectric material). In various embodiments, the material placed in the trenches 1106 is susceptible to ablation by a laser. For example, the material may be an epoxy based buildup layer that flows into the trenches 1106 during a lamination process.

The trenches 1106 and dielectric material may be formed on one side (e.g., the top side as shown) of the glass structure to compensate for the difficulty involved in aligning the lasers used to remove portions of the glass.

At phase 1100D, portions of the buildup layers 1112A and 1112B are removed. For example, a UV laser may be used to ablate portions of the buildup layers 1112A. The portions removed may be in line (in the z-direction) with the glass bridges 1110. The removal may expose one or more surfaces of the glass bridges 1110 and/or may remove the buildup layer material up to a point that is proximate a surface of the glass bridges 1110.

At phase 1100E, portions of the glass bridges 1110 are removed, e.g., by laser ablation or by laser assisted etching and result in the formation of thinner glass bridges 1114A and 1114B. Due to process variations and as depicted, the resulting glass bridges may be asymmetric. For example, the glass bridge 1114A on the left side is thinner than the glass bridge 1114B on the right side.

In various embodiments, the laser applied during phase 1100E is different from (e.g., uses a different wavelength than) the laser applied at phase 1100A and the laser applied during phase 1100D. For example, an IR laser that may remove glass may be used in phase 1100E, whereas a UV laser that removes buildup material but does not remove glass is used in phase 1100D.

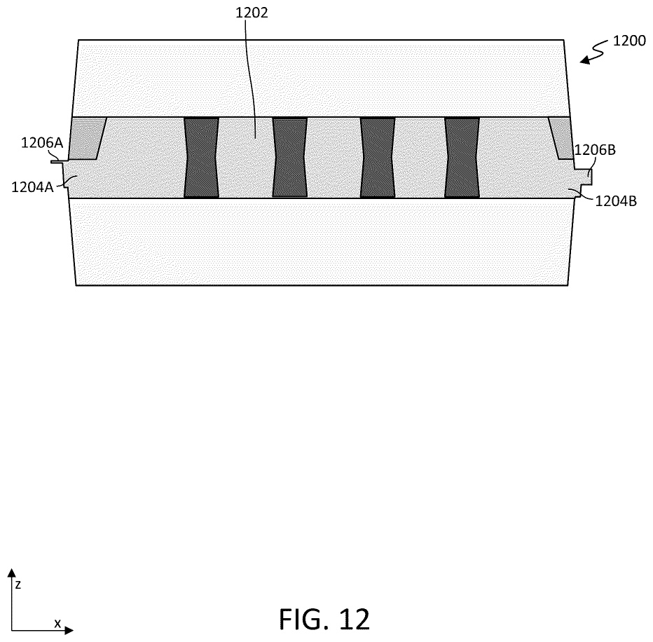

FIG. 12 illustrates a package substrate comprising a glass core and at least one glass protrusion, in accordance with any of the embodiments disclosed herein. The package substrate 1200 represents an example geometry after the package substrate 1200 is singulated (e.g., by applying mechanical force to break through the glass bridges 1114). The glass core of the package substrate includes a core 1202 that includes the majority of the volume of the glass of the package substrate as well as protrusions 1204A and 1204B that extend outward from the glass core (e.g., in the x direction as shown and in the y direction, not shown). Protrusions 1204A and 1204B include portions that remain from the glass bridges 1110. At least a portion of the protrusions 1204A and 1204B are sandwiched between buildup layers. The glass core also includes protrusions 1206A and 1206B which include portions of the glass bridges 1114A and 1114B. In some embodiments, further processing could include polishing or otherwise smoothing the outer sides of the package substrate 1200 and/or applying an edge coating to the outer sides. As alluded to above, the protrusions 1204 may be part of the same protrusion that extends all around the perimeter or may be discrete protrusions. Similarly, protrusions 1406 may each be discrete protrusions or part of the same protrusion that extends all around the perimeter.

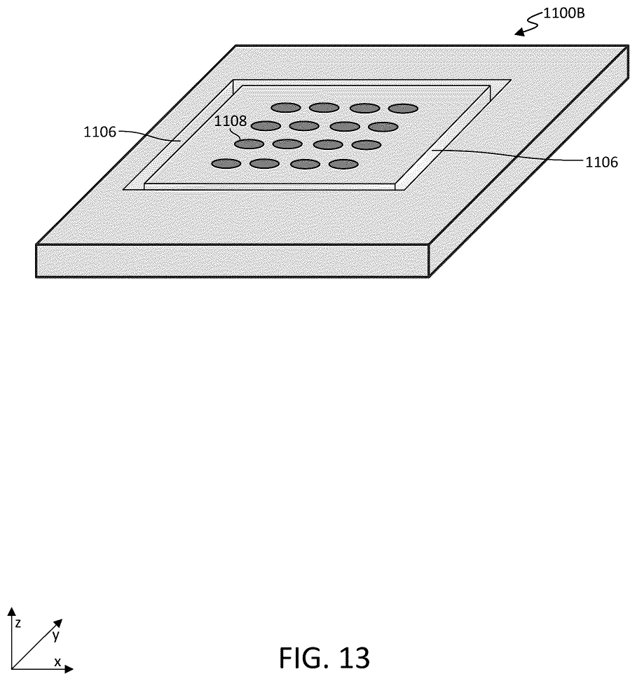

FIG. 13 illustrates a perspective view of a phase 1100B of manufacture of a package substrate comprising a glass core and at least one glass protrusion, in accordance with any of the embodiments disclosed herein. This FIG. represents the view after the trenches 1106 and TGVs 1108 are formed. As depicted the trenches 1106 (and thus the underlying glass bridge 1110, not visible) extend around the perimeter of the active area comprising the TGVs 1108.

As depicted throughout, the glass protrusions may extend from a glass core at various heights in the different embodiments. For example, In FIGS. 2, 5, 8, and 14, at least one glass protrusion extends outward from a point of a glass core that is between a top and a bottom of a glass core. As another example, in FIG. 12, at least one glass protrusion extends outward from a bottom of the glass core (FIG. 12 also depicts another at least one glass protrusion that extends outward from a height that is between a top and bottom of the glass core). As another example, in FIG. 9, at least one glass protrusion extends outward from a top of the glass core and at least one glass protrusion extends outward from a bottom of the glass core.

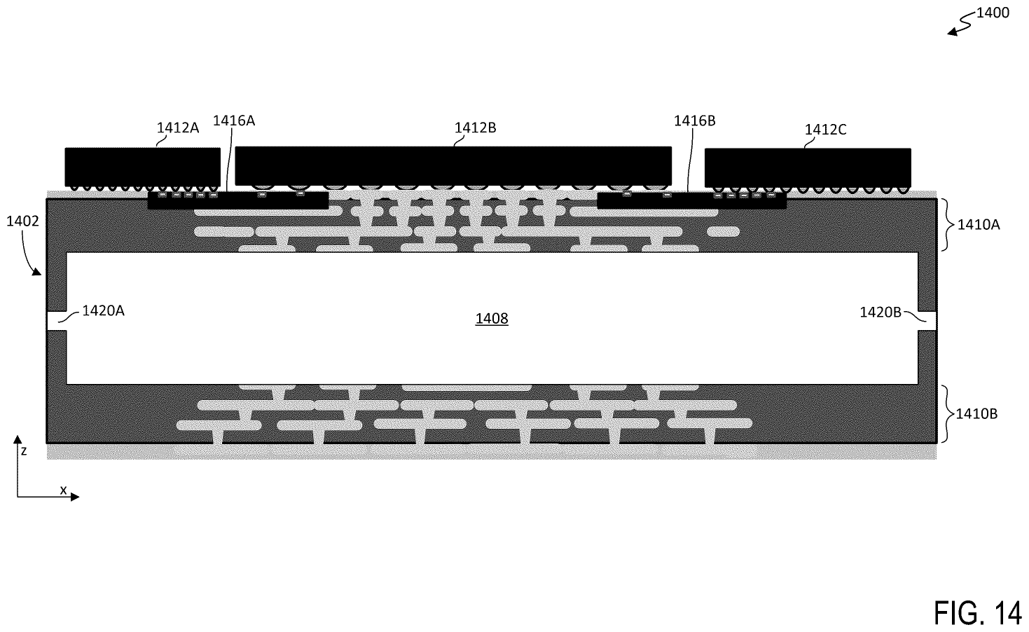

FIG. 14 illustrates a package 1400 comprising a glass core 1408 (which may comprise at least a portion of any of the glass structures described above) and glass protrusions 1420A and 1420B (which could be discrete glass protrusions or different portions of the same glass protrusion). The characteristics of package 1400 may be applied to any of the package substrates described above.

The package 1400 includes a package substrate 1402 which may be formed using any of the steps described above with respect to the various package substrates (and/or other suitable process steps). For example, the package 1400 (or a portion thereof) may be singulated from a panel structure as described above. Thus, the package 1400 (or a portion thereof) may include a glass unit panel. In various embodiments, after singulation is performed on a panel assembly, additional processing may be performed to form a package (e.g., 1400).

The package substrate 1402 may comprise a glass core 1408, a first outer portion 1410A above the glass core 1408, and a second outer portion 1410B below the glass core 1408. The first outer portion 1410A and/or the second outer portion 1410B may each comprise one or more buildup layers. Vias (e.g., TGVs, not shown) may be formed through the glass core 1408.

A first outer portion 1410A and second outer portion 1410B comprising buildup layers are formed respectively on the top and bottom sides of the glass core 1408, with the first outer portion 1410A on the top side of the glass core 1408 and the second outer portion 1410B on the bottom side of the glass core 1408. Any of the buildup layers previously described may have any of the characteristics of other buildup layers described herein.

The buildup layers may comprise alternating conductive layers and insulating layers, where a conductive layer may have any number of different (e.g., electrically isolated) interconnects on the same plane of the package substrate. In some embodiments, a conductive layer may comprise patterned metal (e.g., copper, aluminum, tungsten, gold, etc.) forming signal or power/ground plane layers and may be bordered by one or more dielectric materials to electrically isolate the patterned metal. For example, the buildup layers may include metal traces in metallization layers and pillars between the metallization layers as shown to electrically couple components on the top of the package 1400 with conductive contacts (e.g., pads) at the bottom of the package. For example, the buildup layers may provide connections between IC dies 1412 (e.g., 1412A-C) coupled to the top side of the package and components (e.g., circuits, IC dies, or other electronic devices) coupled to a circuit board (e.g., a motherboard, main board, etc.) through the conductive contacts at the bottom of the package.

The buildup layers may comprise any suitable dielectric materials including one or more of an organic resin (e.g., Ajinomoto Buildup Film), a ceramic, an epoxy film, an epoxy based organic material, inorganic dielectrics (e.g., silicon dioxide, silicon nitride, fluorine-doped silicon dioxide, hydrogen-doped silicon dioxide, etc.), carbon-doped silicon dioxide, photo-imageable dielectric (PID), or suitable filler materials (e.g., silica particle fillers). In some embodiments, a buildup layer comprises an organic resin matrix with different types of fillers (for example, silica fillers of different sizes and/or hollow fillers of different sizes). In some embodiments, the outer portions 1410 (or at least some of the layers of an outer portion) do not have fibers.

A buildup layer may be formed in any suitable manner, such as through placement, lamination, molding (e.g., overmolding), dispensing, deposition, or other suitable method. In one example, a buildup layer is formed by placing a film comprising the buildup layer material onto the glass structure or other underlying layer (e.g., buildup layer) and performing a lamination process. During the lamination process, heat and/or pressure is applied to the buildup layer. In various embodiments, the lamination may be performed in a vacuum chamber. Within the chamber, heat may be applied to melt the material to be laminated and then the material may be pressed onto the panel (and/or onto another layer). Lamination may also involve a curing step in which cross-linking (hardening) of the material occurs.

One side of the package substrate may interface with one or more IC dies 1412. The dies 1412 may include any suitable logic. For example, a die 1412 may comprise an XPU (such as a central processing unit or other processor), a transceiver, a memory, a network interface controller, or other suitable logic.

The top side of the package substrate may include conductive contacts (e.g., solder pads) that couple to conductive contacts of the IC dies 1412 (e.g., via a solder connection). The package substrate may be coupled to any number of IC dies 1412, e.g., via a flip chip technique, wire bonding, and/or other suitable couplings. Another side of the package substrate (e.g., a bottom side) that is opposite to the first side may interface with a circuit board, other integrated circuit dies, and/or passive component structures. For example, solder balls may be formed on conductive contacts and used to couple the conductive contacts of the package 1400 to corresponding conductive contacts of a circuit board and/or other components. A conductive contact may comprise any suitable conductive material (e.g., copper) arranged in any suitable shape. In some examples, the package 1400 has bumps, leads, or pins attached to the package substrate 1402 (either directly or by wires attaching the bumps, leads, or pins to the package substrate) for attaching the package 1400 to a printed circuit board (or motherboard or base board) or another component.

In the depicted embodiment, embedded bridge dies 1416 (e.g., 1416A and 1416B) are embedded within the first outer portion 1410A. An embedded bridge die 1416 may comprise a die with conductive material (e.g., a plurality of metal layers, not explicitly shown) to provide connections between conductive contacts (e.g., pads) of two or more IC dies 1412. The embedded bridge die 1416 may include any suitable passive and/or active components to interconnect IC dies (e.g., 1412A and 1412B or 1412B and 1412C). In some embodiments, the embedded bridge die may be an Intel® embedded multi-die interconnect bridge with through silicon vias (EMIB-T). In various embodiments, an embedded bridge die 1416 comprises a small silicon die embedded in the package substrate under the edges of the dies the respective bridge die couples together.

The package substrate may also include a plurality of TGVs. The TGVs may be vias extending between a first side and a second side of the glass core 1408 (e.g., between the bottom face and the top face of the glass core 1408). The vias may include any appropriate conductive material, e.g., a metal such as copper, silver, nickel, gold, aluminum, or other metals or alloys, for example. The TGVs may be formed using any suitable process, including, for example, a direct laser drilling or laser induced deep etching process. In some embodiments, the TGVs disclosed herein may have a pitch between 50 microns and 500 microns, e.g., as measured from a center of one TGV to a center of an adjacent TGV. The TGVs may have any suitable size and shape. In some embodiments, the TGVs may have a circular, rectangular, or other shaped cross-section. In some embodiments, at least some of the TGVs may have an hourglass shape. In some embodiments, at least some of the TGVs may taper down from one face of the glass core 1408 to another, e.g., from the top face of the glass core 1408 to the bottom face of the glass core 1408. A TGV may provide a conductive path from an interconnect of one conductive layer of the package substrate 1402 to an interconnect of another conductive layer.

In some embodiments, the IC dies 1412 and package substrate 1402 may be encapsulated in a casing material, such as a metal, plastic, glass, or ceramic. The casing may include an integrated heat spreader (IHS).

Where various characteristics are described or illustrated in a particular FIG. for a particular component (e.g., a panel, subpanel, quarter panel, unit panel, core, bridge, protrusion, TGV, package substrate, buildup layer, etc.), the various embodiments described herein contemplate that any suitable combination of such characteristics may also apply to the same component as described or illustrated in another FIG.

As used herein, the term “glass” (e.g., when used in combination with a structure, where structure may refer to a panel, subpanel, quarter panel, unit panel, core, substrate, or the like) may refer to a layer (e.g., a glass layer), a portion of a glass layer, or other structure of any glass material such as quartz, silica, fused silica, silicate glass (e.g., borosilicate, aluminosilicate, alumino-borosilicate), soda-lime glass, soda-lime silica, borofloat glass, lead borate glass, photosensitive glass, non-photosensitive glass, or ceramic glass.

In particular, the glass may be bulk glass or a solid volume/layer of glass, as opposed to, e.g., materials that may include particles of glass, such as glass fiber reinforced polymers (e.g., substrates/boards constructed of glass fibers and an epoxy binder). Such glass materials are typically non-crystalline, often transparent, amorphous solids. In some embodiments, the glass may be an amorphous solid glass layer. In some embodiments, the glass may include a material comprising silicon and oxygen, as well as any one or more of aluminum, boron, magnesium, calcium, barium, tin, sodium, potassium, strontium, phosphorus, zirconium, lithium, titanium, and zinc.

In some embodiments, the glass may include a material, e.g., any of the materials described above, with a weight percentage of silicon being at least about 0.5%, e.g., between about 0.5% and 50%, between about 1% and 48%, or at least about 23%. For example, if the glass is fused silica, the weight percentage of silicon may be about 47%. In some embodiments, the glass may include a material having at least 23% silicon and/or at least 26% oxygen by weight, and, in some further embodiments, the glass may further include at least 5% aluminum by weight.

In some embodiments, the glass may include any of the materials described above and may further include one or more additives such as Al₂O₃, B₂O₃, MgO, CaO, SrO, BaO, SnO₂, Na₂O, K₂O, SrO, P₂O₃, ZrO₂, Li₂O, Ti, and Zn.

In some embodiments, the glass may be a layer of glass that does not include an organic adhesive or an organic material. The glass may be distinguished from, for example, the “prepreg” or “RF4” core of a PCB substrate which typically includes glass fibers embedded in a resinous organic material such as an epoxy.

In such traditional cores/substrates including glass fibers and epoxy, the diameter of the glass fibers is generally in the range of 5 microns to 200 microns. In contrast, in some embodiments, a glass structure (e.g., core, layer, or substrate) may be about 10 millimeters on a side to about 250 millimeters on a side (e.g., 10 millimeters×10 millimeters to 250 millimeters×250 millimeters). In some embodiments, a cross-section of the glass structure in an x-z plane, a y-z plane, and/or an x-y plane of an example coordinate system, may be substantially rectangular. In at least some such embodiments, in the top-down view of a glass structure (e.g., the x-y plane), the glass structure may comprise a solid layer of glass substantially rectangular in shape and may have a first length in a range of 10 millimeters to 250 millimeters, and a second length in a range of 10 millimeters to 250 millimeters, the first length perpendicular to the second length. A thickness of the glass structure (e.g., a dimension measured along the z-axis) may be in a range of about 50 microns to 1.4 millimeters. In some embodiments, the glass structure may be a glass core substrate having a thickness in a range of about 50 microns to 1.4 millimeters. In various embodiments, a multi-layer glass substrate (e.g., a coreless substrate) may be used in a package, wherein a glass layer of the substrate has a thickness in a range of about 25 microns to 50 microns. In some embodiments, the glass structure may be a layer of glass comprising a rectangular prism volume. In some such embodiments, the rectangular prism volume may have a first side and a second side perpendicular to the first side, the first side having a length in a range of 10 millimeters to 250 millimeters and the second side having a length in a range of 10 millimeters to 250 millimeters. In some embodiments, the glass structure may be a rectangular prism volume with sections (e.g., vias) removed and filled with at least one other material (e.g., metal) e.g., through glass vias (TGVs). In some embodiments, the glass structure may be a layer of glass having a thickness in a range of 50 microns to 1.4 millimeters, a first length in a range of 10 millimeters to 250 millimeters, and a second length in a range of 10 millimeters to 250 millimeters, the first length perpendicular to the second length.

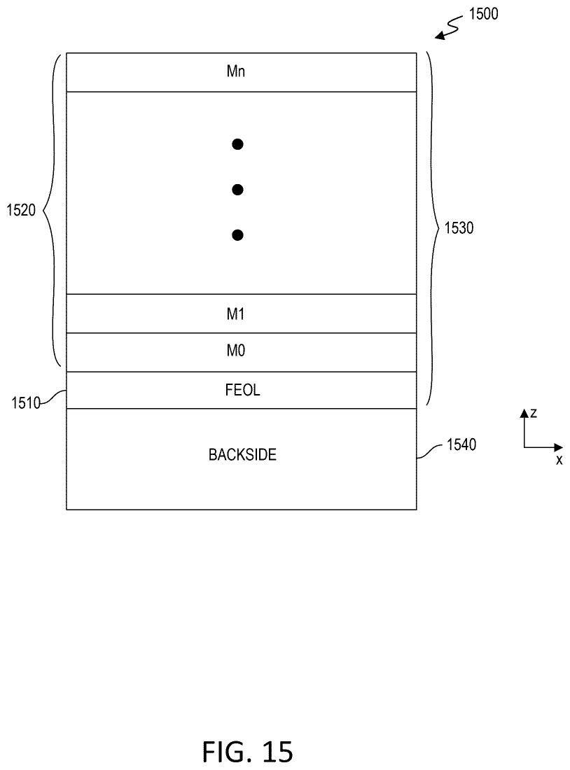

FIG. 15 provides a schematic illustration of a cross-sectional view of an example integrated circuit device (e.g., a chip or die) 1500. The IC device 1500 may include transistors as well as other circuit elements (e.g., resistors, diodes, capacitors, inductors, etc.). The IC device 500 may represent a die that may be attached to a package substrate in various embodiments.

As shown in FIG. 15, the IC device 1500 may include a front side 1530 comprising a front-end-of-line (FEOL) 1510 that includes various logic layers, circuits, and devices to drive and control a logic IC. These circuits and devices may be configured for any number of functions, such as logic or compute transistors, input/output (I/O) transistors, access or switching transistors, and/or radio frequency (RF) transistors, to name a few examples. According to some embodiments, in addition to these devices and circuits, FEOL 1510 may include, for example, one or more other layers or structures associated with the semiconductor devices and circuits. For example, the FEOL can also include a substrate and one or more dielectric layers that surround active and/or conductive portions of the devices and circuits. The FEOL may also include one or more conductive contacts that provide electrical contact to transistor elements such as gate structures, drain regions, or source regions. The FEOL may also include local interconnect (e.g., vias or lines) that connect contacts to interconnect features within a back-end-of-line (BEOL) 1520.

The front side 1530 of the IC device 1500 also includes a BEOL 1520 including various metal interconnect layers (e.g., metal 0 through metal n, where n is any suitable integer). Various metal layers of the BEOL 1520 may be used to interconnect the various inputs and outputs of the FEOL 1510.

Generally speaking, each of the metal layers of the BEOL 1520, e.g., each of the layers M0-Mn shown in FIG. 15, may include a via portion and a trench/interconnect portion. Typically, the trench portion of a metal layer is above the via portion, but, in other embodiments, a trench portion may be provided below a via portion of any given metal layer of the BEOL 1520. The trench portion of a metal layer may be configured for transferring signals and power along metal lines (also sometimes referred to as “trenches”) extending in the x-y plane (e.g., in the x or y directions), while the via portion of a metal layer may be configured for transferring signals and power through metal vias extending in the z-direction, e.g., to any of the adjacent metal layers above or below. Accordingly, vias connect metal structures (e.g., metal lines or vias) from one metal layer to metal structures of an adjacent metal layer. While referred to as “metal” layers, various layers of the BEOL 1520, e.g., layers M0-Mn shown in FIG. 15, may include certain patterns of conductive metals, e.g., copper (Cu) or aluminum (Al), or metal alloys, or more generally, patterns of an electrically conductive material (e.g., including carbon based materials), formed in an insulating medium such as an interlayer dielectric (ILD). The insulating medium may include any suitable ILD materials such as silicon oxide, silicon nitride, aluminum oxide, and/or silicon oxynitride. In various embodiments, any one or more of these layers may additionally include active devices (e.g., transistors, diodes) and/or passive devices (e.g., capacitors, resistors, inductors).

The IC device 1500 may also include a backside 1540. For example, the backside 1540 may formed on the opposite side of a wafer from the front side 1530. In various embodiments, the backside 1540 may include any suitable elements to assist operation of the IC device 1500. For example, the backside 1540 may include various metal layers to deliver power to logic of the FEOL 1510.

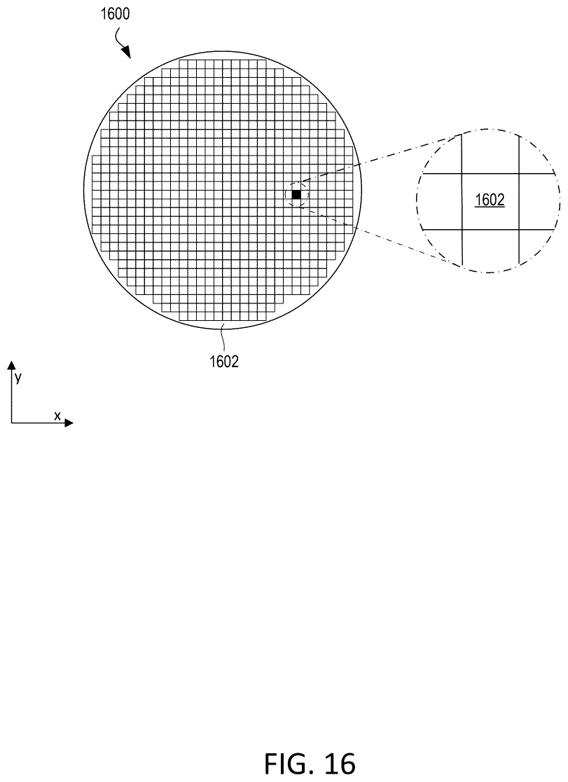

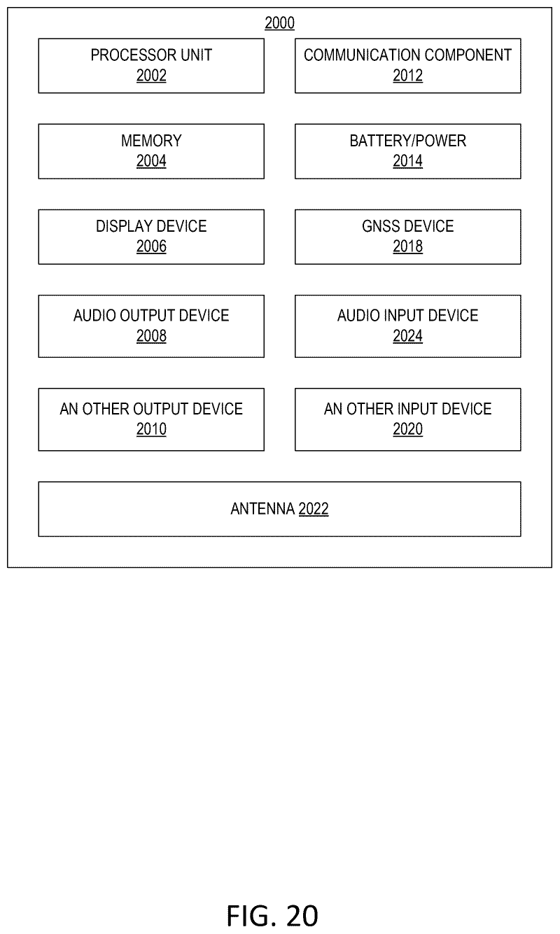

FIG. 16 is a top view of a wafer 1600 and dies 1602, wherein individual dies may be attached to a package substrate with a glass core or other structure(s) as disclosed herein. The wafer 1600 may be composed of semiconductor material and may include one or more dies 1602 having integrated circuit structures formed on a surface of the wafer 1600. The individual dies 1602 may be a repeating unit of an integrated circuit product that includes any suitable integrated circuit. After the fabrication of the semiconductor product is complete, the wafer 1600 may undergo a singulation process in which the dies 1602 are separated from one another to provide discrete “chips” of the integrated circuit product. The die 1602 may include one or more transistors, supporting circuitry to route electrical signals to the transistors, passive components (e.g., signal traces, resistors, capacitors, or inductors), and/or any other integrated circuit components. In some embodiments, the wafer 1600 or the die 1602 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 1602. For example, a memory array formed by multiple memory devices may be formed on a same die 1602 as a processor unit (e.g., the processor unit 2002 of FIG. 20) or other logic that is configured to store information in the memory devices or execute instructions stored in the memory array. In some embodiments, various ones of the microelectronic assemblies disclosed herein may be manufactured using a die-to-wafer assembly technique in which some dies are attached to a wafer 1600 that include other dies, and the wafer 1600 is subsequently singulated.

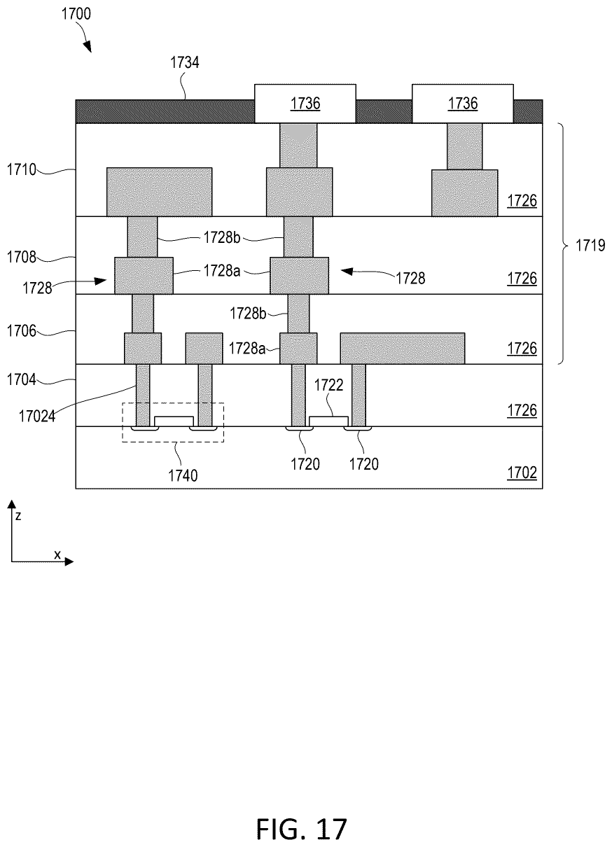

FIG. 17 is a cross-sectional side view of an integrated circuit device 1700 that may be attached to a substrate package with a glass core or other structure(s) as disclosed herein. One or more of the integrated circuit devices 1700 may be included in one or more dies 1602 (FIG. 16). The integrated circuit device 1700 may be formed on a die substrate 1702 (e.g., the wafer 1600 of FIG. 16) and may be included in a die (e.g., the die 1602 of FIG. 16). The die substrate 1702 may be a semiconductor substrate composed of semiconductor material systems including, for example, n-type or p-type materials systems (or a combination of both). The die substrate 1702 may include, for example, a crystalline substrate formed using a bulk silicon or a silicon-on-insulator (SOI) substructure. In some embodiments, the die substrate 1702 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 1702. Although a few examples of materials from which the die substrate 1702 may be formed are described here, any material that may serve as a foundation for an integrated circuit device 1700 may be used. The die substrate 1702 may be part of a singulated die (e.g., the dies 1602 of FIG. 16) or a wafer (e.g., the wafer 1600 of FIG. 16).

The integrated circuit device 1700 may include one or more device layers 1704 disposed on the die substrate 1702. The device layer 1704 may include features of one or more transistors 1740 (e.g., metal oxide semiconductor field-effect transistors (MOSFETs)) formed on the die substrate 1702. The transistors 1740 may include, for example, one or more source and/or drain (S/D) regions 1720, a gate 1722 to control current flow between the S/D regions 1720, and one or more S/D contacts 1724 to route electrical signals to/from the S/D regions 1720. The transistors 1740 may include additional features not depicted for the sake of clarity, such as device isolation regions, gate contacts, and the like. The transistors 1740 are not limited to the type and configuration depicted in FIG. 17 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon, nanosheet, or nanowire transistors.

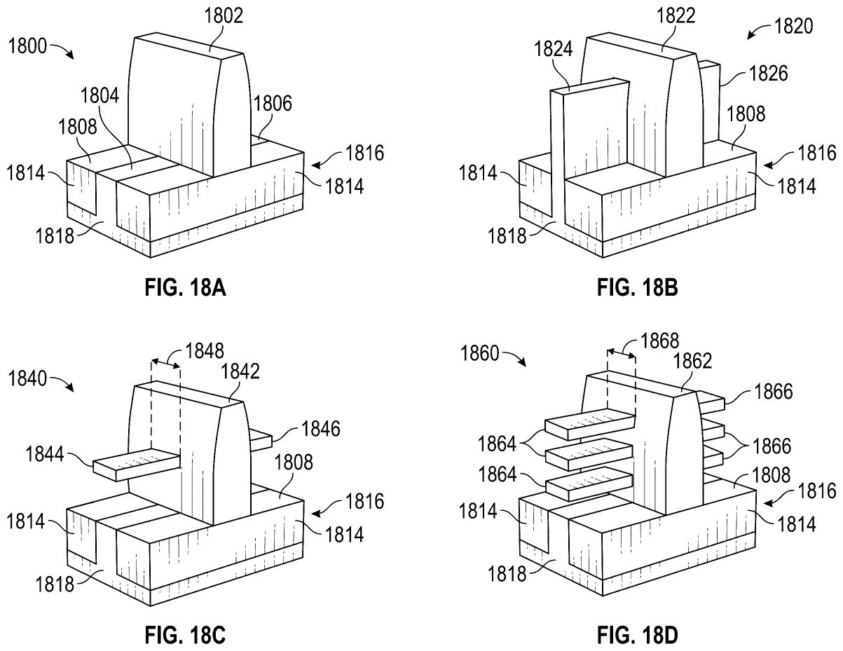

FIGS. 18A-18D are simplified perspective views of example planar, FinFET, gate-all-around, and stacked gate-all-around transistors. The transistors illustrated in FIGS. 18A-18D are formed on a substrate 1816 having a surface 1808. Isolation regions 1814 separate the source and drain regions of the transistors from other transistors and from a bulk region 1818 of the substrate 1816.

FIG. 18A is a perspective view of an example planar transistor 1800 comprising a gate 1802 that controls current flow between a source region 1804 and a drain region 1806. The transistor 1800 is planar in that the source region 1804 and the drain region 1806 are planar with respect to the substrate surface 1808.

FIG. 18B is a perspective view of an example FinFET transistor 1820 comprising a gate 1822 that controls current flow between a source region 1824 and a drain region 1826. The transistor 1820 is non-planar in that the source region 1824 and the drain region 1826 comprise “fins” that extend upwards from the substrate surface 1828. As the gate 1822 encompasses three sides of the semiconductor fin that extends from the source region 1824 to the drain region 1826, the transistor 1820 can be considered a tri-gate transistor. FIG. 18B illustrates one S/D fin extending through the gate 1822, but multiple S/D fins can extend through the gate of a FinFET transistor.

FIG. 18C is a perspective view of a gate-all-around (GAA) transistor 1840 comprising a gate 1842 that controls current flow between a source region 1844 and a drain region 1846. The transistor 1840 is non-planar in that the source region 1844 and the drain region 1846 are elevated from the substrate surface 1828.

FIG. 18D is a perspective view of a GAA transistor 1860 comprising a gate 1862 that controls current flow between multiple elevated source regions 1864 and multiple elevated drain regions 1866. The transistor 1860 is a stacked GAA transistor as the gate controls the flow of current between multiple elevated S/D regions stacked on top of each other. The transistors 1840 and 1860 are considered gate-all-around transistors as the gates encompass all sides of the semiconductor portions that extends from the source regions to the drain regions. The transistors 1840 and 1860 can alternatively be referred to as nanowire, nanosheet, or nanoribbon transistors depending on the width (e.g., widths 1848 and 1868 of transistors 1840 and 1860, respectively) of the semiconductor portions extending through the gate.

Returning to FIG. 17, a transistor 1740 may include a gate 1722 formed of at least two layers, a gate dielectric and a gate electrode. The gate dielectric may include one layer or a stack of layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 1740 is to be a p-type metal oxide semiconductor (PMOS) or an n-type metal oxide semiconductor (NMOS) transistor. In some implementations, the gate electrode may consist of or comprise a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 1740 along the source-channel-drain direction, the gate electrode may consist of or comprise a U-shaped structure that includes a bottom portion substantially parallel to the surface of the die substrate 1702 and two sidewall portions that are substantially perpendicular to the top surface of the die substrate 1702. In other embodiments, at least one of the metal layers that form the gate electrode may simply be a planar layer that is substantially parallel to the top surface of the die substrate 1702 and does not include sidewall portions substantially perpendicular to the top surface of the die substrate 1702. In other embodiments, the gate electrode may consist of or comprise a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 1720 may be formed within the die substrate 1702 adjacent to the gate 1722 of individual transistors 1740. The S/D regions 1720 may be formed using an implantation/diffusion process or an etching/deposition process, for example. In the former process, dopants such as boron, aluminum, antimony, phosphorous, or arsenic may be ion-implanted into the die substrate 1702 to form the S/D regions 1720. An annealing process that activates the dopants and causes them to diffuse farther into the die substrate 1702 may follow the ion-implantation process. In the latter process, the die substrate 1702 may first be etched to form recesses at the locations of the S/D regions 1720. An epitaxial deposition process may then be carried out to fill the recesses with material that is used to fabricate the S/D regions 1720. In some implementations, the S/D regions 1720 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1720 may be formed using one or more alternate semiconductor materials such as germanium or a group III-V material or alloy. In further embodiments, one or more layers of metal and/or metal alloys may be used to form the S/D regions 1720.

Electrical signals, such as power and/or input/output (I/O) signals, may be routed to and/or from the devices (e.g., transistors 1740) of the device layer 1704 through one or more interconnect layers disposed on the device layer 1704 (illustrated in FIG. 17 as interconnect layers 1706-1710). For example, electrically conductive features of the device layer 1704 (e.g., the gate 1722 and the S/D contacts 1724) may be electrically coupled with the interconnect structures 1728 of the interconnect layers 1706-1710. The one or more interconnect layers 1706-1710 may form a metallization stack (also referred to as an “ILD stack”) 1719 of the integrated circuit device 1700.

The interconnect structures 1728 (e.g., lines) may be arranged within the interconnect layers 1706-1710 to route electrical signals according to a wide variety of designs; in particular, the arrangement is not limited to the particular configuration of interconnect structures 1728 depicted in FIG. 17. Although a particular number of interconnect layers 1706-1710 is depicted in FIG. 17, embodiments of the present disclosure include integrated circuit devices having more or fewer interconnect layers than depicted.

In some embodiments, the interconnect structures 1728 may include lines 1728a and/or vias 1728b filled with an electrically conductive material such as a metal. The lines 1728a may be arranged to route electrical signals in a direction of a plane that is substantially parallel with a surface of the die substrate 1702 upon which the device layer 1704 is formed. For example, the lines 1728a may route electrical signals in a direction in and out of the page and/or in a direction across the page. The vias 1728b may be arranged to route electrical signals in a direction of a plane that is substantially perpendicular to the surface of the die substrate 1702 upon which the device layer 1704 is formed. In some embodiments, the vias 1728b may electrically couple lines 1728a of different interconnect layers 1706-1710 together.

The interconnect layers 1706-1710 may include a dielectric material 1726 disposed between the interconnect structures 1728, as shown in FIG. 17. In some embodiments, dielectric material 1726 disposed between the interconnect structures 1728 in different ones of the interconnect layers 1706-1710 may have different compositions; in other embodiments, the composition of the dielectric material 1726 between different interconnect layers 1706-1710 may be the same. The device layer 1704 may include a dielectric material 1726 disposed between the transistors 1740 and a bottom layer of the metallization stack as well. The dielectric material 1726 included in the device layer 1704 may have a different composition than the dielectric material 1726 included in the interconnect layers 1706-1710; in other embodiments, the composition of the dielectric material 1726 in the device layer 1704 may be the same as a dielectric material 1726 included in any one of the interconnect layers 1706-1710.

A first interconnect layer 1706 (referred to as Metal 1 or “M1”) may be formed directly on the device layer 1704. In some embodiments, the first interconnect layer 1706 may include lines 1728a and/or vias 1728b, as shown. The lines 1728a of the first interconnect layer 1706 may be coupled with contacts (e.g., the S/D contacts 1724) of the device layer 1704. The vias 1728b of the first interconnect layer 1706 may be coupled with the lines 1728a of a second interconnect layer 1708.

The second interconnect layer 1708 (referred to as Metal 2 or “M2”) may be formed directly on the first interconnect layer 1706. In some embodiments, the second interconnect layer 1708 may include via 1728b to couple the lines 1728a of the second interconnect layer 1708 with the lines 1728a of a third interconnect layer 1710. Although the lines 1728a and the vias 1728b are structurally delineated with a line within individual interconnect layers for the sake of clarity, the lines 1728a and the vias 1728b may be structurally and/or materially contiguous (e.g., simultaneously filled during a dual-damascene process) in some embodiments.

The third interconnect layer 1710 (referred to as Metal 3 or “M3”) (and additional interconnect layers, as desired) may be formed in succession on the second interconnect layer 1708 according to similar techniques and configurations described in connection with the second interconnect layer 1708 or the first interconnect layer 1706. In some embodiments, the interconnect layers that are “higher up” in the metallization stack 1719 in the integrated circuit device 1700 (i.e., farther away from the device layer 1704) may be thicker that the interconnect layers that are lower in the metallization stack 1719, with lines 1728a and vias 1728b in the higher interconnect layers being thicker than those in the lower interconnect layers.

The integrated circuit device 1700 may include a solder resist material 1734 (e.g., polyimide or similar material) and one or more conductive contacts 1736 formed on the interconnect layers 1706-1710. In FIG. 17, the conductive contacts 1736 are illustrated as taking the form of bond pads. The conductive contacts 1736 may be electrically coupled with the interconnect structures 1728 and configured to route the electrical signals of the transistor(s) 1740 to external devices. For example, solder bonds may be formed on the one or more conductive contacts 1736 to mechanically and/or electrically couple an integrated circuit die including the integrated circuit device 1700 with another component (e.g., a printed circuit board). The integrated circuit device 1700 may include additional or alternate structures to route the electrical signals from the interconnect layers 1706-1710; for example, the conductive contacts 1736 may include other analogous features (e.g., posts) that route the electrical signals to external components.

In some embodiments in which the integrated circuit device 1700 is a double-sided die, the integrated circuit device 1700 may include another metallization stack (not shown) on the opposite side of the device layer(s) 1704. This metallization stack may include multiple interconnect layers as discussed above with reference to the interconnect layers 1706-1710, to provide conductive pathways (e.g., including conductive lines and vias) between the device layer(s) 1704 and additional conductive contacts (not shown) on the opposite side of the integrated circuit device 1700 from the conductive contacts 1736.

In other embodiments in which the integrated circuit device 1700 is a double-sided die, the integrated circuit device 1700 may include one or more through silicon vias (TSVs) through the die substrate 1702; these TSVs may make contact with the device layer(s) 1704, and may provide conductive pathways between the device layer(s) 1704 and additional conductive contacts (not shown) on the opposite side of the integrated circuit device 1700 from the conductive contacts 1736. In some embodiments, TSVs extending through the substrate can be used for routing power and ground signals from conductive contacts on the opposite side of the integrated circuit device 1700 from the conductive contacts 1736 to the transistors 1740 and any other components integrated into the integrated circuit device (e.g., die) 1700, and the metallization stack 1719 can be used to route I/O signals from the conductive contacts 1736 to transistors 1740 and any other components integrated into the integrated circuit device (e.g., die) 1700.

Multiple integrated circuit devices 1700 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

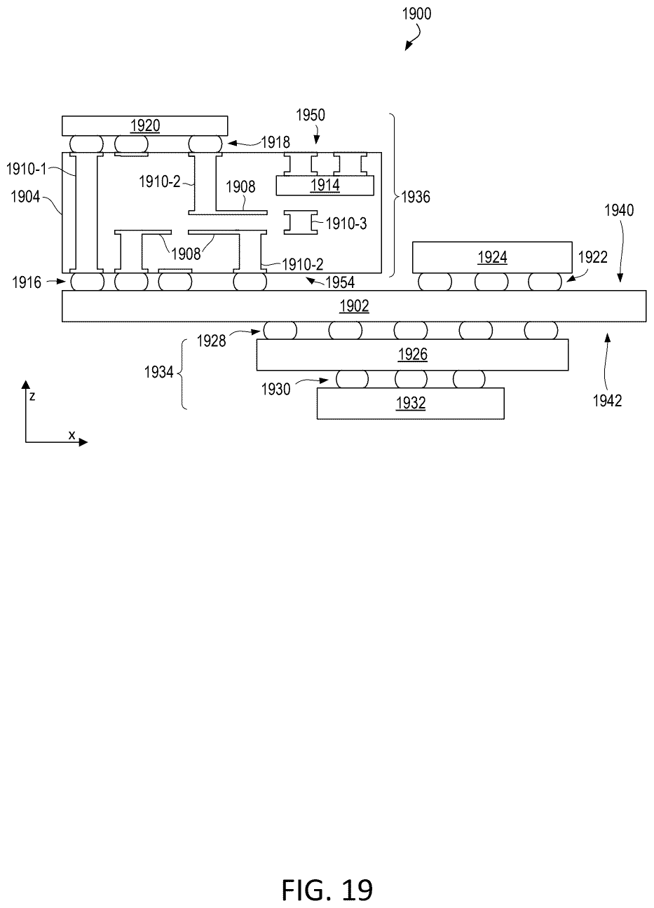

FIG. 19 is a cross-sectional side view of an integrated circuit device assembly 1900 that may include a substrate package with a glass core or other structure(s) as disclosed herein. In some embodiments, the integrated circuit device assembly 1900 may be a microelectronic assembly. The integrated circuit device assembly 1900 includes a number of components disposed on a circuit board 1902 (which may be a motherboard, system board, mainboard, etc.). The integrated circuit device assembly 1900 includes components disposed on a first face 1940 of the circuit board 1902 and an opposing second face 1942 of the circuit board 1902; generally, components may be disposed on one or both faces 1940 and 1942.

In some embodiments, the circuit board 1902 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 1902. In other embodiments, the circuit board 1902 may be a non-PCB substrate. The integrated circuit device assembly 1900 illustrated in FIG. 19 includes a package-on-interposer structure 1936 coupled to the first face 1940 of the circuit board 1902 by coupling components 1916. The coupling components 1916 may electrically and mechanically couple the package-on-interposer structure 1936 to the circuit board 1902, and may include solder balls (as shown in FIG. 19), pins (e.g., as part of a pin grid array (PGA), contacts (e.g., as part of a land grid array (LGA)), male and female portions of a socket, an adhesive, an underfill material, and/or any other suitable electrical and/or mechanical coupling structure.

The package-on-interposer structure 1936 may include an integrated circuit component 1920 coupled to an interposer 1904 by coupling components 1918. The coupling components 1918 may take any suitable form for the application, such as the forms discussed above with reference to the coupling components 1916. Although a single integrated circuit component 1920 is shown in FIG. 19, multiple integrated circuit components may be coupled to the interposer 1904; indeed, additional interposers may be coupled to the interposer 1904. The interposer 1904 may provide an intervening substrate used to bridge the circuit board 1902 and the integrated circuit component 1920.

The integrated circuit component 1920 may be a packaged or unpackaged integrated circuit product that includes one or more integrated circuit dies (e.g., the die 1602 of FIG. 16, the integrated circuit device 1700 of FIG. 17) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 1920, a single monolithic integrated circuit die comprises solder bumps attached to contacts on the die. The solder bumps allow the die to be directly attached to the interposer 1904. The integrated circuit component 1920 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 1920 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 1920 comprises multiple integrated circuit dies, the dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 1920 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 1904 may spread connections to a wider pitch or reroute a connection to a different connection. For example, the interposer 1904 may couple the integrated circuit component 1920 to a set of ball grid array (BGA) conductive contacts of the coupling components 1916 for coupling to the circuit board 1902. In the embodiment illustrated in FIG. 19, the integrated circuit component 1920 and the circuit board 1902 are attached to opposing sides of the interposer 1904; in other embodiments, the integrated circuit component 1920 and the circuit board 1902 may be attached to a same side of the interposer 1904. In some embodiments, three or more components may be interconnected by way of the interposer 1904.

In some embodiments, the interposer 1904 may be formed as a PCB, including multiple metal layers separated from one another by layers of dielectric material and interconnected by electrically conductive vias. In some embodiments, the interposer 1904 may be formed of an epoxy resin, a fiberglass-reinforced epoxy resin, an epoxy resin with inorganic fillers, a ceramic material, or a polymer material such as polyimide. In some embodiments, the interposer 1904 may be formed of alternate rigid or flexible materials that may include the same materials described above for use in a semiconductor substrate, such as silicon, germanium, and other group III-V and group IV materials. The interposer 1904 may include metal interconnects 1908 and vias 1910, including but not limited to through hole vias 1910-1 (that extend from a first face 1950 of the interposer 1904 to a second face 1954 of the interposer 1904), blind vias 1910-2 (that extend from the first or second faces 1950 or 1954 of the interposer 1904 to an internal metal layer), and buried vias 1910-3 (that connect internal metal layers).

In some embodiments, the interposer 1904 can comprise a silicon interposer. Through silicon vias (TSV) extending through the silicon interposer can connect connections on a first face of a silicon interposer to an opposing second face of the silicon interposer. In some embodiments, an interposer 1904 comprising a silicon interposer can further comprise one or more routing layers to route connections on a first face of the interposer 1904 to an opposing second face of the interposer 1904.

The interposer 1904 may further include embedded devices 1914, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1904. The package-on-interposer structure 1936 may take the form of any of the package-on-interposer structures known in the art.

The integrated circuit device assembly 1900 may include an integrated circuit component 1924 coupled to the first face 1940 of the circuit board 1902 by coupling components 1922. The coupling components 1922 may take the form of any of the embodiments discussed above with reference to the coupling components 1916, and the integrated circuit component 1924 may take the form of any of the embodiments discussed above with reference to the integrated circuit component 1920.

The integrated circuit device assembly 1900 illustrated in FIG. 19 includes a package-on-package structure 1934 coupled to the second face 1942 of the circuit board 1902 by coupling components 1928. The package-on-package structure 1934 may include an integrated circuit component 1926 and an integrated circuit component 1932 coupled together by coupling components 1930 such that the integrated circuit component 1926 is disposed between the circuit board 1902 and the integrated circuit component 1932. The coupling components 1928 and 1930 may take the form of any of the embodiments of the coupling components 1916 discussed above, and the integrated circuit components 1926 and 1932 may take the form of any of the embodiments of the integrated circuit component 1920 discussed above. The package-on-package structure 1934 may be configured in accordance with any of the package-on-package structures known in the art.

FIG. 20 is a block diagram of an example electrical device 2000 that may include a substrate package with a glass core or other structure(s) as disclosed herein. For example, any suitable components of the electrical device 2000 may include one or more of the integrated circuit device assemblies 1900, integrated circuit components 1920, integrated circuit devices 1700, integrated circuit dies 1602, or other components disclosed herein. A number of components are illustrated in FIG. 20 as included in the electrical device 2000, but any one or more of these components may be omitted or duplicated, as suitable for the application. In some embodiments, some or all of the components included in the electrical device 2000 may be attached to one or more motherboards mainboards, or system boards. In some embodiments, one or more of these components are fabricated onto a single system-on-a-chip (SoC) die.

Additionally, in various embodiments, the electrical device 2000 may not include one or more of the components illustrated in FIG. 20, but the electrical device 2000 may include interface circuitry for coupling to the one or more components. For example, the electrical device 2000 may not include a display device 2006, but may include display device interface circuitry (e.g., a connector and driver circuitry) to which a display device 2006 may be coupled. In another set of examples, the electrical device 2000 may not include an audio input device 2024 or an audio output device 2008, but may include audio input or output device interface circuitry (e.g., connectors and supporting circuitry) to which an audio input device 2024 or audio output device 2008 may be coupled.

The electrical device 2000 may include one or more processor units 2002 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 2002 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 2000 may include a memory 2004, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 2004 may include memory that is located on the same integrated circuit die as the processor unit 2002. This memory may be used as cache memory (e.g., Level 1 (L1), Level 2 (L2), Level 3 (L3), Level 4 (L4), Last Level Cache (LLC)) and may include embedded dynamic random access memory (eDRAM) or spin transfer torque magnetic random access memory (STT-MRAM).

In some embodiments, the electrical device 2000 can comprise one or more processor units 2002 that are heterogeneous or asymmetric to another processor unit 2002 in the electrical device 2000. There can be a variety of differences between the processing units 2002 in a system in terms of a spectrum of metrics of merit including architectural, microarchitectural, thermal, power consumption characteristics, and the like. These differences can effectively manifest themselves as asymmetry and heterogeneity among the processor units 2002 in the electrical device 2000.

In some embodiments, the electrical device 2000 may include a communication component 2012 (e.g., one or more communication components). For example, the communication component 2012 can manage wireless communications for the transfer of data to and from the electrical device 2000. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 2012 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 2012 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 2012 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 2012 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 2012 may operate in accordance with other wireless protocols in other embodiments. The electrical device 2000 may include an antenna 2022 to facilitate wireless communications and/or to receive other wireless communications (such as amplitude modulation (AM) or frequency modulation (FM) radio transmissions).

In some embodiments, the communication component 2012 may manage wired communications, such as electrical, optical, or any other suitable communication protocols (e.g., IEEE 802.3 Ethernet standards). As noted above, the communication component 2012 may include multiple communication components. For instance, a first communication component 2012 may be dedicated to shorter-range wireless communications such as Wi-Fi or Bluetooth, and a second communication component 2012 may be dedicated to longer-range wireless communications such as global positioning system (GPS), EDGE, GPRS, CDMA, WiMAX, LTE, EV-DO, or others. In some embodiments, a first communication component 2012 may be dedicated to wireless communications, and a second communication component 2012 may be dedicated to wired communications.

The electrical device 2000 may include battery/power circuitry 2014. The battery/power circuitry 2014 may include one or more energy storage devices (e.g., batteries or capacitors) and/or circuitry for coupling components of the electrical device 2000 to an energy source separate from the electrical device 2000 (e.g., AC line power).

The electrical device 2000 may include a display device 2006 (or corresponding interface circuitry, as discussed above). The display device 2006 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 2000 may include an audio output device 2008 (or corresponding interface circuitry, as discussed above). The audio output device 2008 may include any embedded or wired or wirelessly connected external device that generates an audible indicator, such speakers, headsets, or earbuds.

The electrical device 2000 may include an audio input device 2024 (or corresponding interface circuitry, as discussed above). The audio input device 2024 may include any embedded or wired or wirelessly connected device that generates a signal representative of a sound, such as microphones, microphone arrays, or digital instruments (e.g., instruments having a musical instrument digital interface (MIDI) output). The electrical device 2000 may include a Global Navigation Satellite System (GNSS) device 2018 (or corresponding interface circuitry, as discussed above), such as a Global Positioning System (GPS) device. The GNSS device 2018 may be in communication with a satellite-based system and may determine a geolocation of the electrical device 2000 based on information received from one or more GNSS satellites, as known in the art.

The electrical device 2000 may include an other output device 2010 (or corresponding interface circuitry, as discussed above). Examples of the other output device 2010 may include an audio codec, a video codec, a printer, a wired or wireless transmitter for providing information to other devices, or an additional storage device.

The electrical device 2000 may include an other input device 2020 (or corresponding interface circuitry, as discussed above). Examples of the other input device 2020 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 2000 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 2000 may be any other electronic device that processes data. In some embodiments, the electrical device 2000 may comprise multiple discrete physical components. Given the range of devices that the electrical device 2000 can be manifested as in various embodiments, in some embodiments, the electrical device 2000 can be referred to as a computing device or a computing system.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein.

It will also be understood that, although the terms “first,” “second,” and so forth may be used herein to describe various elements, these elements should not be limited by these terms. These terms are only used to distinguish one element from another and are not intended to imply that the objects so described must be in a given sequence, either temporally, spatially, in ranking or in any other manner. For example, a first contact could be termed a second contact, and, similarly, a second contact could be termed a first contact, without departing from the scope of the present example embodiments. The first contact and the second contact are both contacts, but they are not the same contact.

As used in the description of the example embodiments and the appended examples, the singular forms “a,” “an,” and “the” are intended to include the plural forms as well, unless the context clearly indicates otherwise. It will also be understood that the term “and/or” as used herein refers to and encompasses any and all possible combinations of one or more of the associated listed items. For example, the phrase “A and/or B” means (A), (B), or (A and B), while the phrase “A, B, and/or C” means (A), (B), (C), (A and B), (A and C), (B and C), or (A, B, and C).

As used throughout this description, and in the claims, a list of items joined by the term “at least one of”or “one or more of”can mean any combination of the listed terms.

It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. Furthermore, the terms “comprising,” “including,” “having,” and the like, as used with respect to embodiments of the present disclosure, are synonymous.

The description may use the phrases “in an embodiment,” “according to some embodiments,” “in accordance with embodiments,” or “in embodiments,” which may each refer to one or more of the same or different embodiments.

As used herein, the term “module” refers to being part of, or including an ASIC, an electronic circuit, a system on a chip, a processor (shared, dedicated, or group), a solid state device, a memory (shared, dedicated, or group) that execute one or more software or firmware programs, a combinational logic circuit, and/or other suitable components that provide the described functionality.

As used herein, “electrically conductive” in some examples may refer to a property of a material having an electrical conductivity greater than or equal to 10⁷ Siemens per meter (S/m) at 20 degrees Celsius. Examples of such materials include Cu, Ag, Al, Au, W, Zn and Ni.

The term “signal” may refer to at least one current signal, voltage signal, magnetic signal, or data/clock signal.

Throughout the specification, and in the claims, the term “connected” means a direct connection, such as electrical, mechanical, or magnetic connection between the elements that are connected, without any intermediary devices. The term “coupled” means a direct or indirect connection, such as a direct electrical, mechanical, or magnetic connection between the elements that are connected or an indirect connection, through one or more passive or active intermediary devices.

The description may use perspective-based descriptions such as top/bottom, in/out, over/under, and the like. Such descriptions are merely used to facilitate the discussion and are not intended to restrict the application of embodiments described herein to any particular orientation.

The terms “over,” “under,” “between,” and “on” as used herein refer to a relative position of one component or material with respect to other components or materials where such physical relationships are noteworthy. For example, in the context of materials, one material or layer over or under another may be directly in contact or may have one or more intervening materials or layers. Moreover, one material between two materials or layers may be directly in contact with the two materials/layers or may have one or more intervening materials/layers. In contrast, a first material or layer “on” a second material or layer means that at least a part of the first material or layer is in direct physical contact with at least a part of that second material/layer. Similar distinctions are to be made in the context of component assemblies.

As used herein, “A is proximate to B” may mean that A is adjacent to B or A is otherwise near to B.

Unless otherwise specified in the specific context of use, the term “predominantly” means more than 50%, or more than half. For example, a composition that is predominantly a first constituent means more than half of the composition (e.g., by volume) is the first constituent (e.g., >50 at. %). The term “primarily” means the most, or greatest, part. For example, a composition that is primarily a first constituent means the composition has more of the first constituent (e.g., by volume) than any other constituent. A composition that is primarily first and second constituents means the composition has more of the first and second constituents than any other constituent. The term “substantially” means there is only incidental variation. For example, composition that is substantially a first constituent means the composition may further include <1% of any other constituent. A composition that is substantially first and second constituents means the composition may further include <1% of any constituent substituted for either the first or second constituent.

The terms “substantially,” “close,” “approximately,” “near,” and “about,” generally refer to being within +/−10% of a target value (unless specifically specified).

Unless otherwise specified in the explicit context of their use, the terms “substantially equal,” “about equal” or “approximately equal” mean that there is no more than incidental variation between two things so described. In the art, such variation is typically no more than +/−10% of a predetermined target value.

In the corresponding drawings of the embodiments, signals, currents, electrical biases, or magnetic or electrical polarities may be represented with lines. Some lines may be thicker, to indicate more constituent signal paths, and/or have arrows at one or more ends, to indicate primary information flow direction. Such indications are not intended to be limiting. Rather, the lines are used in connection with one or more exemplary embodiments to facilitate easier understanding of a circuit or a logical unit. Any represented signal, polarity, current, voltage, etc., as dictated by design needs or preferences, may actually comprise one or more signals that may travel in either direction and may be implemented with any suitable type of signal scheme.

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements.

Although the figures may illustrate embodiments where structures are substantially aligned to Cartesian axes (e.g., device structures having substantially vertical sidewalls), positive and negative (re-entrant) sloped feature sidewalls often occur in practice. For example, manufacturing non-idealities may cause one or more structural features to have sloped sidewalls. Thus, attributes illustrated are idealized merely for the sake of clearly describing salient features. It is to be understood that schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication.

Illustrative examples of the technologies described throughout this disclosure are provided below. Embodiments of these technologies may include any one or more, and any combination of, the examples described below. In some embodiments, at least one of the systems or components set forth in one or more of the preceding figures may be configured to perform one or more operations, techniques, processes, and/or methods as set forth in the following examples.

Example 1 includes an apparatus comprising a package substrate comprising a glass structure; at least one buildup layer above the glass structure; and at least one buildup layer below the glass structure; wherein the glass structure comprises a first portion having a first thickness and a second portion that extends outward from the first portion, wherein the second portion has a second thickness that is smaller than the first thickness.

Example 2 includes the subject matter of Example 1, and wherein the second portion extends outward from a point of the first portion that is between a top and a bottom of the first portion.

Example 3 includes the subject matter of any of Examples 1 and 2, and wherein the second portion extends outward from a top of the first portion.

Example 4 includes the subject matter of any of Examples 1-3, and wherein the second portion extends outward from a bottom of the first portion.

Example 5 includes the subject matter of any of Examples 1-4, and wherein the glass structure further comprises a third portion that extends outward from the first portion, the third portion having a third thickness that is smaller than the first thickness.

Example 6 includes the subject matter of any of Examples 1-5, and wherein the second portion extends outward from a top of the first portion and wherein the third portion extends outward from a bottom of the first portion.

Example 7 includes the subject matter of any of Examples 1-6, and wherein the second portion forms a perimeter around the first portion.

Example 8 includes the subject matter of any of Examples 1-7, and further including an integrated circuit package comprising the package substrate, wherein the integrated circuit package comprises at least one integrated circuit die coupled to the package substrate.

Example 9 includes the subject matter of any of Examples 1-8, and further including at least one of a network interface, battery, or memory coupled to the integrated circuit die.

Example 10 includes the subject matter of any of Examples 1-9, and further including a printed circuit board coupled to the package substrate.

Example 11 includes an apparatus comprising an integrated circuit package substrate comprising a glass layer having a first thickness; a first plurality of buildup layers above the glass layer; a second plurality of buildup layers below the glass layer; a protrusion extending from the glass layer, the protrusion having a second thickness that is smaller than the first thickness.

Example 12 includes the subject matter of Example 11, and wherein the protrusion forms a perimeter around the glass layer in a horizontal plane.

Example 13 includes the subject matter of any of Examples 11 and 12, and wherein a buildup layer of the first plurality of buildup layers is in contact with a top surface of the protrusion and a top surface of the glass layer.

Example 14 includes the subject matter of any of Examples 11-13, and wherein a buildup layer of the second plurality of buildup layers is in contact with a bottom surface of the protrusion and a bottom surface of the glass layer.

Example 15 includes the subject matter of any of Examples 11-14, and wherein the integrated circuit package substrate further comprises a plurality of protrusions extending from the glass layer, wherein the plurality of protrusions are each thinner than the glass layer.

Example 16 includes the subject matter of any of Examples 11-15, and wherein the protrusion extends outward from a point of the glass layer that is between a top and a bottom of the glass layer.

Example 17 includes the subject matter of any of Examples 11-16, and wherein the protrusion extends outward from a top of the glass layer.

Example 18 includes the subject matter of any of Examples 11-17, and wherein the protrusion extends outward from a bottom of the glass layer.

Example 19 includes the subject matter of any of Examples 11-18, and wherein the glass structure further comprises a second protrusion that extends outward from the glass layer, the second protrusion having a third thickness that is smaller than the first thickness.

Example 20 includes the subject matter of any of Examples 11-19, and wherein the protrusion extends outward from a top of the glass layer and wherein the second protrusion extends outward from a bottom of the glass layer.

Example 21 includes the subject matter of any of Examples 11-20, and wherein the protrusion forms a perimeter around the glass layer.

Example 22 includes the subject matter of any of Examples 11-21, and further including an integrated circuit package comprising the package substrate, wherein the integrated circuit package comprises at least one integrated circuit die coupled to the package substrate.

Example 23 includes the subject matter of any of Examples 11-22, and further including at least one of a network interface, battery, or memory coupled to the integrated circuit die.

Example 24 includes the subject matter of any of Examples 11-23, and further including a printed circuit board coupled to the package substrate.

Example 25 includes a system comprising a glass core; a plurality of through glass vias formed through the glass core; at least one first dielectric layer above the glass core; at least one second dielectric layer below the glass core; and a glass protrusion extending in a horizontal direction from the glass core, wherein the glass protrusion is thinner than the glass core.

Example 26 includes the subject matter of Example 25, and wherein the glass protrusion surrounds the glass core.

Example 27 includes the subject matter of any of Examples 25 and 26, and further including a plurality of glass protrusions extending horizontally from the glass core.

Example 28 includes the subject matter of any of Examples 25-27, and further including a plurality of integrated circuit dies above the at least one first dielectric layer.

Example 29 includes the subject matter of any of Examples 25-28, and further including a bridge embedded within the at least one dielectric layer above the glass core, wherein the bridge is coupled to a first integrated circuit die and a second integrated circuit die of the plurality of integrated circuit dies.

Example 30 includes the subject matter of any of Examples 25-29, and wherein the glass protrusion forms a perimeter around the glass core in a horizontal plane.

Example 31 includes the subject matter of any of Examples 25-30, and wherein a dielectric layer of the first plurality of dielectric layers is in contact with a top surface of the glass protrusion and a top surface of the glass core.

Example 32 includes the subject matter of any of Examples 25-31, and wherein a dielectric layer of the second plurality of dielectric layers is in contact with a bottom surface of the glass protrusion and a bottom surface of the glass core.

Example 33 includes the subject matter of any of Examples 25-32, and wherein the system further comprises a plurality of glass protrusions extending from the glass core, wherein the plurality of protrusions are each thinner than the glass layer.

Example 34 includes the subject matter of any of Examples 25-33, and wherein the glass protrusion extends outward from a point of the glass core that is between a top and a bottom of the glass core.

Example 35 includes the subject matter of any of Examples 25-34, and wherein the glass protrusion extends outward from a top of the glass core.

Example 36 includes the subject matter of any of Examples 25-35, and wherein the glass protrusion extends outward from a bottom of the glass core.

Example 37 includes the subject matter of any of Examples 25-36, and wherein the system further comprises a second glass protrusion that extends outward from the glass core, the second glass protrusion having a third thickness that is smaller than the first thickness.

Example 38 includes the subject matter of any of Examples 25-37, and wherein the glass protrusion extends outward from a top of the glass core and wherein the second glass protrusion extends outward from a bottom of the glass core.

Example 39 includes the subject matter of any of Examples 25-38, and wherein the glass protrusion forms a perimeter around the glass core.

Example 40 includes the subject matter of any of Examples 25-39, and further including an integrated circuit package comprising a package substrate comprising the glass core and glass protrusion, wherein the integrated circuit package comprises at least one integrated circuit die coupled to the package substrate.

Example 41 includes the subject matter of any of Examples 25-40, and further including at least one of a network interface, battery, or memory coupled to the integrated circuit die.

Example 42 includes the subject matter of any of Examples 25-41, and further including a printed circuit board coupled to the package substrate.

Example 43 includes a method comprising forming glass bridges in a glass structure by removing portions of glass from a glass structure; and singulating the glass structure along the glass bridges to form a plurality of glass units.

Example 44 includes the subject matter of Example 43, wherein removing portions of glass from a glass structure comprises performing laser induced deep etching.

Example 45 includes the subject matter of any of Examples 43-44, wherein the glass bridges have thicknesses that are less than the thickness of the glass structure.

Example 46 includes the subject matter of any of Examples 43-45, and further including forming a plurality of through-holes in the glass structure using a laser that is different from a laser used to remove the portions of glass to form the glass bridges.

Example 47 includes forming a glass core; forming a plurality of through glass vias through the glass core; forming at least one first dielectric layer above the glass core; forming at least one second dielectric layer below the glass core; and forming a glass protrusion extending in a horizontal direction from the glass core, wherein the glass protrusion is thinner than the glass core.

Example 48 includes the subject matter of Example 47, and wherein the glass protrusion surrounds the glass core.

Example 49 includes the subject matter of any of Examples 47 and 48, and further including forming a plurality of glass protrusions extending horizontally from the glass core.

Example 50 includes the subject matter of any of Examples 47-49, and further including attaching a plurality of integrated circuit dies above the at least one first dielectric layer.

Example 51 includes the subject matter of any of Examples 47-50, and further including embedding a bridge within the at least one dielectric layer above the glass core, and coupling the bridge to a first integrated circuit die and a second integrated circuit die of the plurality of integrated circuit dies.

Example 52 includes the subject matter of any of Examples 47-51, and wherein the glass protrusion forms a perimeter around the glass core in a horizontal plane.

Example 53 includes the subject matter of any of Examples 47-52, and wherein a dielectric layer of the first plurality of dielectric layers is in contact with a top surface of the glass protrusion and a top surface of the glass core.

Example 54 includes the subject matter of any of Examples 47-53, and wherein a dielectric layer of the second plurality of dielectric layers is in contact with a bottom surface of the glass protrusion and a bottom surface of the glass core.

Example 55 includes the subject matter of any of Examples 47-54, and wherein the system further comprises a plurality of glass protrusions extending from the glass core, wherein the plurality of protrusions are each thinner than the glass layer.

Example 56 includes the subject matter of any of Examples 47-55, and wherein the glass protrusion extends outward from a point of the glass core that is between a top and a bottom of the glass core.

Example 57 includes the subject matter of any of Examples 47-56, and wherein the glass protrusion extends outward from a top of the glass core.

Example 58 includes the subject matter of any of Examples 47-57, and wherein the glass protrusion extends outward from a bottom of the glass core.

Example 59 includes the subject matter of any of Examples 47-58, and further including forming a second glass protrusion that extends outward from the glass core, the second glass protrusion having a third thickness that is smaller than the first thickness.

Example 60 includes the subject matter of any of Examples 47-59, and wherein the glass protrusion extends outward from a top of the glass core and wherein the second glass protrusion extends outward from a bottom of the glass core.

Example 61 includes the subject matter of any of Examples 47-60, and wherein the glass protrusion forms a perimeter around the glass core.

Example 62 includes the subject matter of any of Examples 47-61, and further including forming an integrated circuit package comprising a package substrate comprising the glass core and glass protrusion, wherein the integrated circuit package comprises at least one integrated circuit die coupled to the package substrate.

Example 63 includes the subject matter of any of Examples 47-62, and further including attaching at least one of a network interface, battery, or memory to the integrated circuit die.

Example 64 includes the subject matter of any of Examples 47-63, and further including attaching a printed circuit board to the package substrate.

Example 65 includes the subject matter of any of Examples 47-64, and wherein the glass protrusion extends from a first side of the glass core and from a second side of the glass core, wherein the first side is opposite to the second side.

The foregoing description, for the purpose of explanation, has been described with reference to specific example embodiments. However, the illustrative discussions above are not intended to be exhaustive or to limit the possible example embodiments to the precise forms disclosed. Many modifications and variations are possible in view of the above teachings. The example embodiments were chosen and described in order to best explain the principles involved and their practical applications, to thereby enable others skilled in the art to best utilize the various example embodiments with various modifications as are suited to the particular use contemplated.

1. An apparatus comprising:
a package substrate comprising:
a glass structure;
at least one buildup layer above the glass structure; and
at least one buildup layer below the glass structure;
wherein the glass structure comprises a first portion having a first thickness and a second portion that extends outward from the first portion, wherein the second portion has a second thickness that is smaller than the first thickness.

2. The apparatus of claim 1, wherein the second portion extends outward from a point of the first portion that is between a top and a bottom of the first portion.

3. The apparatus of claim 1, wherein the second portion extends outward from a top of the first portion.

4. The apparatus of claim 1, wherein the second portion extends outward from a bottom of the first portion.

5. The apparatus of claim 1, wherein the glass structure further comprises a third portion that extends outward from the first portion, the third portion having a third thickness that is smaller than the first thickness.

6. The apparatus of claim 5, wherein the second portion extends outward from a top of the first portion and wherein the third portion extends outward from a bottom of the first portion.

7. The apparatus of claim 1, wherein the second portion forms a perimeter around the first portion.

8. The apparatus of claim 1, further comprising an integrated circuit package comprising the package substrate, wherein the integrated circuit package comprises at least one integrated circuit die coupled to the package substrate.

9. The apparatus of claim 8, further comprising at least one of a network interface, battery, or memory coupled to the at least one integrated circuit die.

10. The apparatus of claim 8, further comprising a printed circuit board coupled to the package substrate.

11. An apparatus comprising:
an integrated circuit package substrate comprising:
a glass layer having a first thickness;
a first plurality of buildup layers above the glass layer;
a second plurality of buildup layers below the glass layer; and
a protrusion extending from the glass layer, the protrusion having a second thickness that is smaller than the first thickness.

12. The apparatus of claim 11, wherein the protrusion forms a perimeter around the glass layer in a horizontal plane.

13. The apparatus of claim 11, wherein a buildup layer of the first plurality of buildup layers is in contact with a top surface of the protrusion and a top surface of the glass layer.

14. The apparatus of claim 11, wherein a buildup layer of the second plurality of buildup layers is in contact with a bottom surface of the protrusion and a bottom surface of the glass layer.

15. The apparatus of claim 11, wherein the integrated circuit package substrate further comprises a plurality of protrusions extending from the glass layer, wherein the plurality of protrusions are each thinner than the glass layer.

16. A system comprising:
a glass core;
a plurality of through glass vias formed through the glass core;
at least one first dielectric layer above the glass core;
at least one second dielectric layer below the glass core; and
a glass protrusion extending in a horizontal direction from the glass core, wherein the glass protrusion is thinner than the glass core.

17. The system of claim 16, wherein the glass protrusion surrounds the glass core.

18. The system of claim 16, wherein the glass protrusion extends from a first side of the glass core and from a second side of the glass core, wherein the first side is opposite to the second side.

19. The system of claim 16, further comprising a plurality of glass protrusions extending horizontally from the glass core.

20. The system of claim 16, further comprising a plurality of integrated circuit dies above the at least one first dielectric layer.
